(19) United States
(12) Patent Application Publication
(10) Pub. No.: US 2026/0173725 A1
(43) Pub. Date: Jun. 18, 2026

(54) ROOF REMOVAL FOR OLED DEVICE

(71) Applicant: Applied Materials, Inc., Santa Clara, CA (US)

(72) Inventors: Sheng-Wen WANG, Tainan City (TW); Chung-Chia CHEN, Hsinchu City (TW); Ji Young CHOUNG, Hwaseong-si (KR); Yu-Hsin LIN, Zhubei City (TW)

(21) Appl. No.: 19/364,444

(22) Filed: Oct. 21, 2025

Related U.S. Application Data
(60) Provisional application No. 63/734,450, filed on Dec. 16, 2024.

(51) Int. Cl. H10K 59/80; H10K 59/12; H10K 59/122

(52) U.S. Cl. CPC H10K 59/873; H10K 59/1201; H10K 59/122

(57) ABSTRACT

Embodiments described herein relate to a sub-pixel circuit and methods of forming a sub-pixel circuit. The sub-pixel circuit includes a substrate and a plurality of sub-pixels defined by adjacent pixel structures. Each sub-pixel includes the adjacent pixel structures disposed over the substrate, an anode, an organic light emitting diode (OLED) material disposed over the anode, a cathode disposed over the OLED material, and an encapsulation layer disposed over the cathode. Each pixel structure includes a first structure disposed over the substrate. The encapsulation layer includes an encapsulation overhang extending from a sidewall of the first structure and having an upper surface coplanar with a top surface of the first structure. A gap is defined between the encapsulation layer and a portion of the encapsulation layer disposed over the cathode. The global layer is disposed on the top surface of the first structure and the upper surface of the encapsulation overhang.

### CROSS-REFERENCE TO RELATED APPLICATIONS

This application claims the benefit of U.S. Patent Application No. 63/734,450, filed on December 16, 2024, the contents of which are herein incorporated by reference.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today’s electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits and methods of forming sub-pixel circuits to increase pixel-per-inch and provide improved OLED performance.

### SUMMARY

In one embodiment, a device is provided. The device includes a substrate and a plurality of sub-pixels defined by adjacent pixel structures. Each sub-pixel includes the adjacent pixel structures disposed over the substrate, an anode, an organic light emitting diode (OLED) material disposed over the anode, a cathode disposed over the OLED material, an encapsulation layer disposed over the cathode, and a global layer disposed over the encapsulation layer. Each pixel structure includes a first structure disposed over the substrate. The encapsulation layer includes an encapsulation overhang extending from a sidewall of the first structure and having an upper surface coplanar with a top surface of the first structure. A gap is defined between the encapsulation overhang and a portion of the encapsulation layer disposed over the cathode. The global layer is disposed on the top surface of the first structure and the upper surface of the encapsulation overhang.

In another embodiment, a method of forming a device is provided. The device includes a substrate and a plurality of sub-pixels defined by adjacent pixel structures. Each sub-pixel includes the adjacent pixel structures disposed over the substrate, an anode, an organic light emitting diode (OLED) material disposed over the anode, a cathode disposed over the OLED material, an encapsulation layer disposed over the cathode, and a global layer disposed over the encapsulation layer. Each pixel structure includes a first structure disposed over the substrate. The encapsulation layer includes an encapsulation overhang extending from a sidewall of the first structure and having an upper surface coplanar with a top surface of the first structure. A gap is defined between the encapsulation overhang and a portion of the encapsulation layer disposed over the cathode. A panel cover layer disposed over the plurality of sub-pixels. The panel cover layer is disposed on the upper surface of the first structure and the upper surface of the encapsulation overhang. The global passivation layer disposed over the panel cover layer.

In another embodiment, a method of forming a device is provided. The method includes disposing a first resist in a plurality of sub-pixels of a sub-pixel circuit, wherein the sub-pixel circuit are defined by adjacent pixel structures. Each adjacent pixel structures includes a first structure disposed over a substrate, a second structure disposed over a first structure, an anode, an organic light emitting diode (OLED) material disposed over the anode, a cathode disposed over the OLED material, and an encapsulation layer disposed over the cathode. The second structure comprises an overhang extension extending laterally past an upper surface of a first structure to form an overhang. The OLED material is disposed under the overhang and extends to contact a sidewall of the first structure. The cathode is disposed under the overhang and extends past an endpoint of the OLED material to contact the sidewall of the first structure. The encapsulation layer is disposed under the overhang and extends past an endpoint of the cathode to contact the sidewall of the first structure. A portion of the first resist is removed to expose a portion of the encapsulation layer. The portion of the encapsulation layer that is exposed by the first resist is removed to expose the second structures. The first resist is removed. A second resist is disposed in a plurality of sub-pixels. A portion of the second resist is removed to expose the second structures. The second structures exposed by the second resist are removed. The second resist is removed.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A is a schematic, cross-sectional view of a sub-pixel circuit, according to embodiments.

FIG. 1B is a portion of the schematic, cross-sectional view of a portion of the sub-pixel circuit of FIG. 1A, according to embodiments.

FIG. 2 is a flow diagram of a method for forming a sub-pixel circuit of FIG. 1, according to embodiments.

FIGS. 3A-3M are schematic, cross-sectional views of a substrate during the method of FIG. 2 for forming the sub-pixel circuit of FIG. 1A, according to embodiments.

FIG. 4 is a flow diagram of a method for forming a sub-pixel circuit of FIG. 1A, according to embodiments.

FIGS. 5A-5J are schematic, cross-sectional views of a substrate during the method of FIG. 4 for forming the sub-pixel circuit of FIG. 1A, according to embodiments.

FIG. 6A is a schematic, cross-sectional view of a sub-pixel circuit without the encapsulation overhangs, according to embodiments.

FIG. 6B is a portion of the schematic, cross-sectional view of a portion of the sub-pixel circuit, according to embodiments.

FIG. 7 is a flow diagram of a method for forming a sub-pixel circuit of FIG. 6A, according to embodiments.

FIGS. 8A-8G are schematic, cross-sectional views of a substrate during the method of FIG. 7 for forming the sub-pixel circuit of FIG. 6A, according to embodiments.

FIG. 9A is a schematic, cross-sectional view of a sub-pixel circuit with intermediate structure, according to embodiments.

FIG. 9B is a portion of the schematic, cross-sectional view of a portion of the sub-pixel circuit of FIG. 9A, according to embodiments.

FIG. 10 is a flow diagram of a method for forming a sub-pixel circuit of FIG. 9A, according to embodiments.

FIGS. 11A-11F are schematic, cross-sectional views of a substrate during the method of FIG. 10 for forming the sub-pixel circuit of FIG. 9A, according to embodiments.

FIG. 12 is a flow diagram of a method for forming the sub-pixel circuit of FIG. 1A, according to embodiments.

FIGS. 13A-13D are schematic, cross-sectional views of a substrate during the method of FIG. 12 for forming the sub-pixel circuit of FIG. 1A, according to embodiments.

FIG. 14A is a schematic, cross-sectional view of a sub-pixel circuit with second structures, according to embodiments.

FIG. 14B is a portion of the schematic, cross-sectional view of a portion of the sub-pixel circuit of FIG. 14A, according to embodiments.

FIG. 15 is a flow diagram of a method 1500 for forming a sub-pixel circuit, according to embodiments.

FIGS. 16A-16K are schematic, cross-sectional views of a substrate during the method for forming the sub-pixel circuit of FIG. 14A, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In various embodiments, the sub-pixels employ advanced pixel structures to improve functionality of the display.

Each of the embodiments described herein of the sub-pixel circuit include a plurality of sub-pixels with each of the sub-pixels defined by adjacent pixel structures that are permanent to the sub-pixel circuit. While the Figures depict two sub-pixels with each sub-pixel defined by pixel structures, the sub-pixel circuit of the embodiments described herein include a plurality of sub-pixels, such as two or more subpixels. Each sub-pixel has OLED materials configured to emit a white, red, green, blue or other color light when energized, e.g., the OLED materials of a first sub-pixel emits a red light when energized, the OLED materials of a second sub-pixel emits a green light when energized, and the OLED materials of a third sub-pixel emits a blue light when energized.

The pixel structures are permanent to the sub-pixel circuit and include at least a first structure. The adjacent pixel structures defining each sub-pixel of the sub-pixel circuit of the display provide for formation of the sub-pixel circuit using evaporation deposition and provide for the pixel structures to remain in place after the sub-pixel circuit is formed. Evaporation deposition is utilized for deposition of OLED materials (including a hole injection layer (HIL), a hole transport layer (HTL), an emissive layer (EML), and an electron transport layer (ETL)), and cathode. In some instances, an encapsulation layer may be disposed via evaporation deposition. In embodiments including one or more capping layers, the capping layers are disposed between the cathode and the encapsulation layer. The pixel structures and the evaporation angle set by the evaporation source define the deposition angles, i.e., the pixel structures provide for a shadowing effect during evaporation deposition with the evaporation angle set by the evaporation source. In order to deposit at a particular angle, the evaporation source is configured to emit the deposition material at a particular angle with regard to the pixel structure. The encapsulation layer of a respective subpixel is disposed over the cathode with the encapsulation layer extending along a sidewall of each of the adjacent pixel structures.

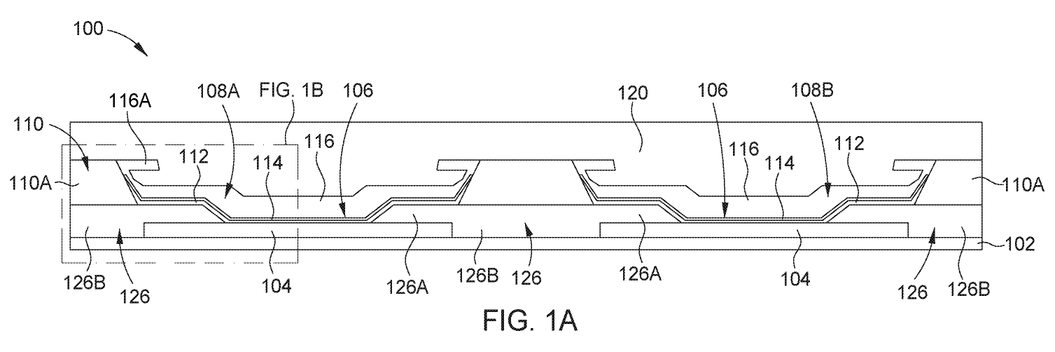

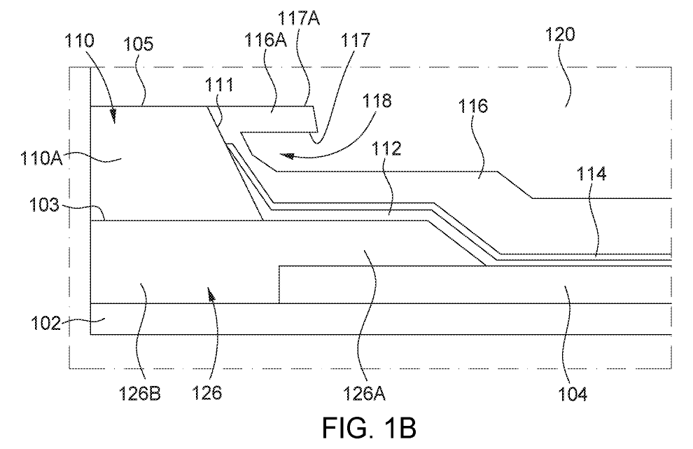

FIG. 1A is a schematic, cross-sectional view of a sub-pixel circuit 100. FIG. 1B is a portion of the schematic, cross-sectional view of a portion of the sub-pixel circuit 100. The sub-pixel circuit 100 includes a substrate 102. Metal-containing layers (e.g., anodes 104) may be patterned on the substrate 102 and are defined by adjacent separation structures 126 disposed on the substrate 102. In one embodiment, which may be combined with other embodiments, the anodes 104 are pre-patterned on the substrate 102. E.g., the substrate 102 is pre-patterned with anodes 104 of indium tin oxide (ITO). The anodes 104 are configured to operate as anodes of respective sub-pixels. In one embodiment, which may be combined with other embodiments, the anode 104 is a layer stack of a first transparent conductive oxide (TCO) layer, a second metal-containing layer disposed on the first TCO layer, and a third TCO layer disposed on the second metal-containing layer. The anodes 104 include, but are not limited to, chromium, titanium, gold, silver, copper, aluminum, ITO, a combination thereof, or other suitably conductive materials.

The separation structures 126 are disposed over the substrate 102. The separation structures 126 include one of an organic material, an organic material with an inorganic coating disposed thereover, or an inorganic material. In some embodiments, which may be combined with other embodiments, the separation structures 126 may be an electrically insulative polymer. The organic material of the separation structures 126 includes, but is not limited to, polyimides. The inorganic material of the separation structures 126 includes, but is not limited to, silicon oxide (SiO₂), silicon nitride (Si₃N₄), silicon oxynitride (Si₂N₂O), magnesium fluoride (MgF₂), or combinations thereof. Adjacent separation structures 126 define a respective sub-pixels and expose the anode 104 of the respective sub-pixel circuit 100. The separation structures 126 includes a separation structure extension portion 126A and a separation structure body portion 126B. The separation structure extension portion 126A extends over an upper surface of the anode 104. The separation structure body portion 126B is disposed on over the substrate 102.

The sub-pixel circuit 100 has a plurality of sub-pixels 106, including at least a first sub-pixel 108A and second sub-pixel 108B. While FIG. 1 depicts the first sub-pixel 108A and the second sub-pixel 108B, the sub-pixel circuit 100 of the embodiments described herein may include two or more sub-pixels, such as a third sub-pixel and a fourth sub-pixel. Each sub-pixel has OLED materials configured to emit a white, red, green, blue or other color light when energized, e.g., the OLED materials of the first sub-pixel 108A emits a red light when energized, the OLED materials of the second sub-pixel 108B emits a green light when energized, the OLED materials of a third sub-pixel emits a blue light when energized, and the OLED materials of a fourth sub-pixel emits another color light when energized.

Each sub-pixel 106 includes adjacent pixel structures 110, with adjacent sub-pixels sharing the adjacent pixel structures 110. The pixel structures 110 are permanent to the sub-pixel circuit 100. The pixel structures 110 further define each sub-pixel 106 of the sub-pixel circuit 100. Each adjacent pixel structures includes a first structure 110A. The first structure 110A is disposed over the substrate 102. In some examples, which may be combined with other embodiments, the first structure 110A is disposed over an upper surface 103 of the separation structure 126. In one example, which may be combined with other embodiments, the first structure 110A includes a conductive inorganic material. In another example, the first structure 110A includes a non-conductive inorganic material. The conductive materials include a copper (Cu), aluminum (Al), aluminum neodymium (AlNd), molybdenum (Mo), molybdenum tungsten (MoW), titanium (Ti), or combinations thereof. The non-conductive materials include amorphous silicon (a-Si), silicon nitride (Si₃N₄), silicon oxide (SiO₂), silicon oxynitride (Si₂N₂O), germanium (Ge), germanium arsenide (GeAs III or IV), or combinations thereof. The pixel structures 110 are able to remain in place, i.e., are permanent.

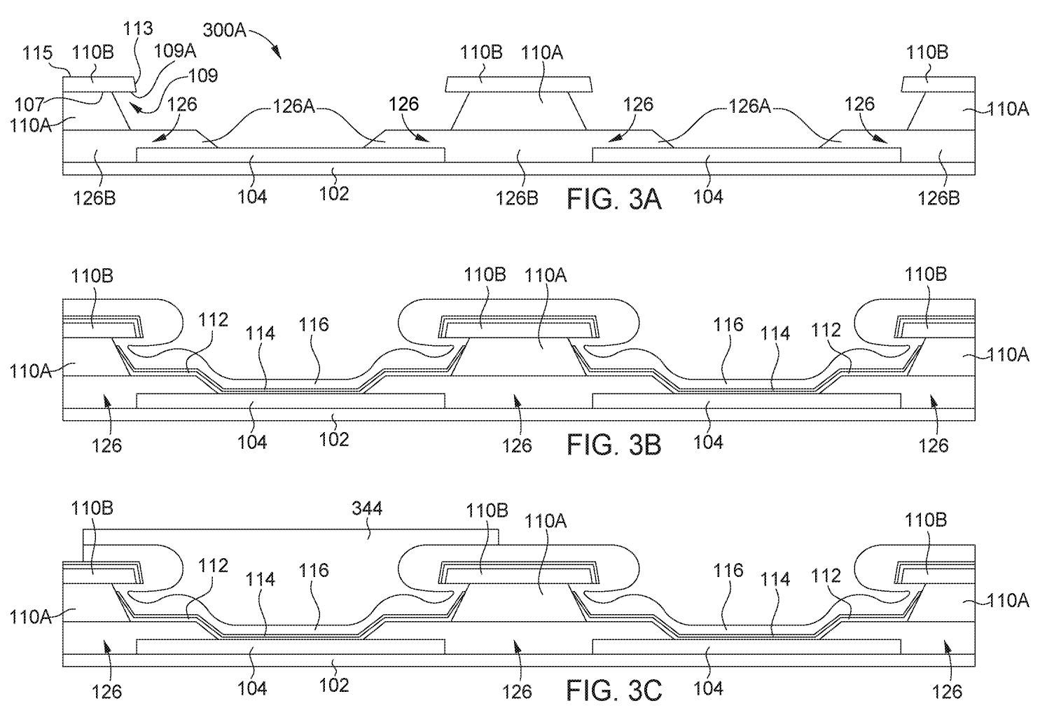

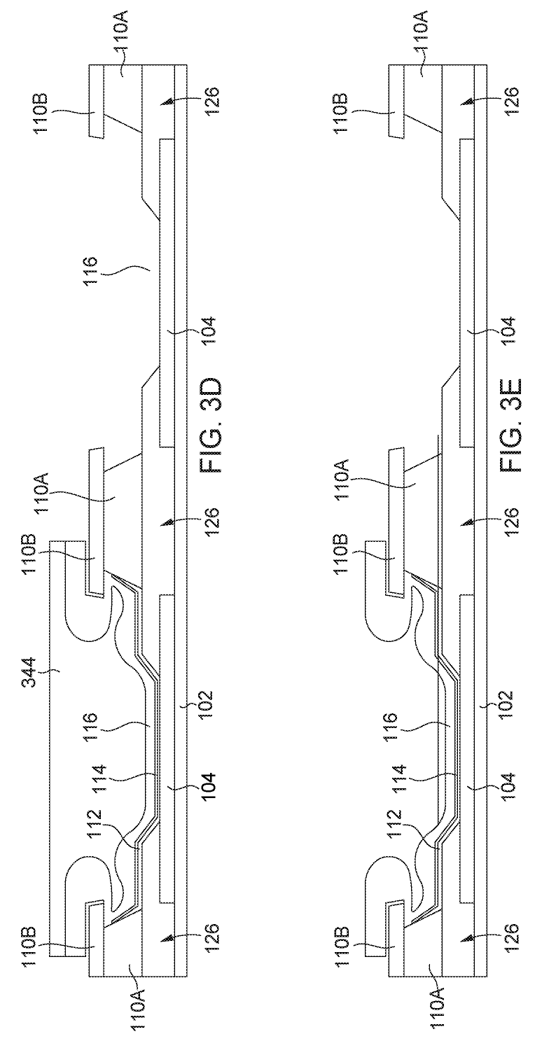

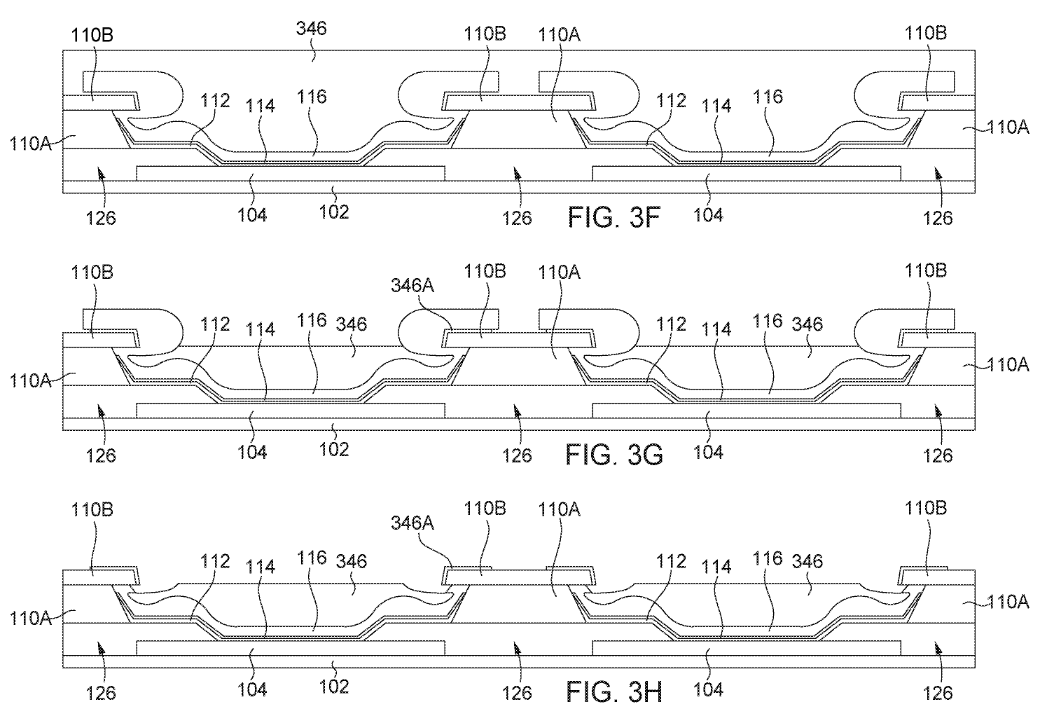

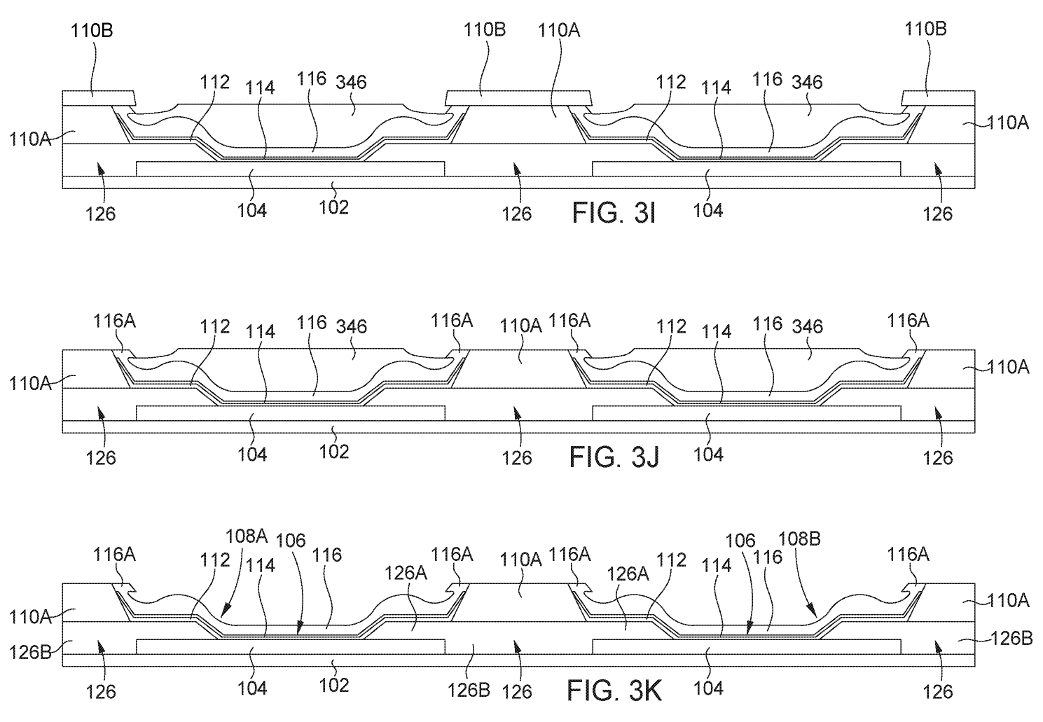

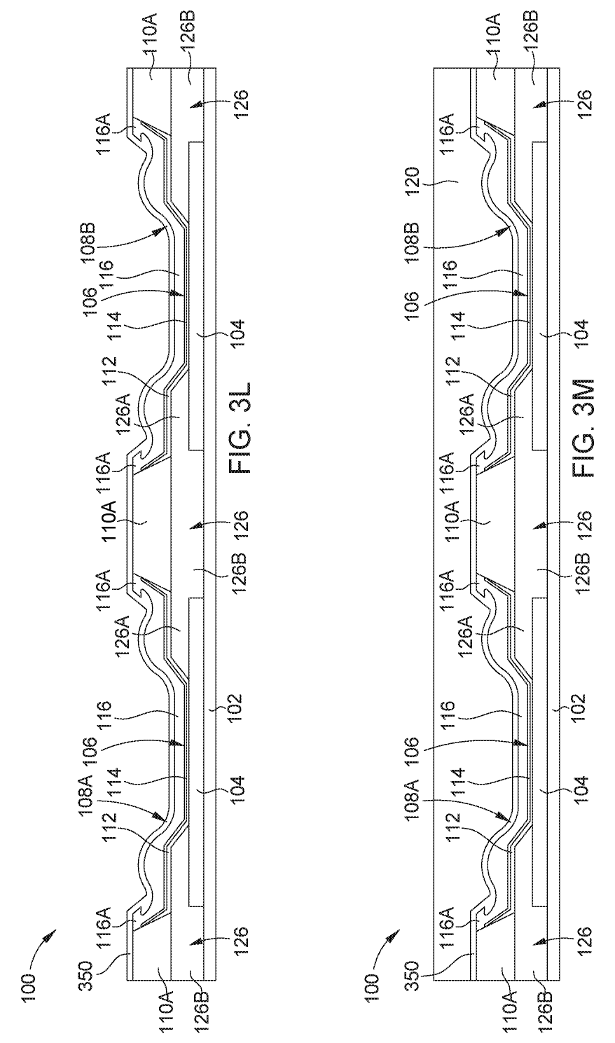

During manufacture of the sub-pixel circuit 100 (e.g., during methods 200 and 400, as discussed in further detail below), the adjacent pixel structures 110 include adjacent overhangs 109 of a second structure 110B (as shown in FIG. 3D). The adjacent overhangs 109 are defined by an overhang extension 109A (as shown in FIG. 3D) of the second structure 110B extending laterally past an upper surface 105 of a first structure 110A. The second structure 110B is disposed over the first structure 110A. The second structure 110B may be disposed on the upper surface 105 of the first structure 110A. At least the bottom surface 107 (as shown in FIG. 3D) of the second structure 110B is wider than the upper surface 105 of the first structure 110A to form the overhang extension 109A. In one example, which may be combined with other embodiments, the second structure 110B includes a conductive inorganic material. In another example, the second structure 110B includes a non-conductive inorganic material. The conductive materials include a copper (Cu), aluminum (Al), aluminum neodymium (AlNd), molybdenum (Mo), molybdenum tungsten (MoW), titanium (ti), or combinations thereof. The non-conductive materials include amorphous silicon (a-Si), silicon nitride (Si₃N₄), silicon oxide (SiO₂), silicon oxynitride (Si₂N₂O), germanium (Ge), germanium arsenide (GeAs III or IV), or combinations thereof. In some embodiments, the second structure 110B may include a transparent conductive oxide (TCO) material.

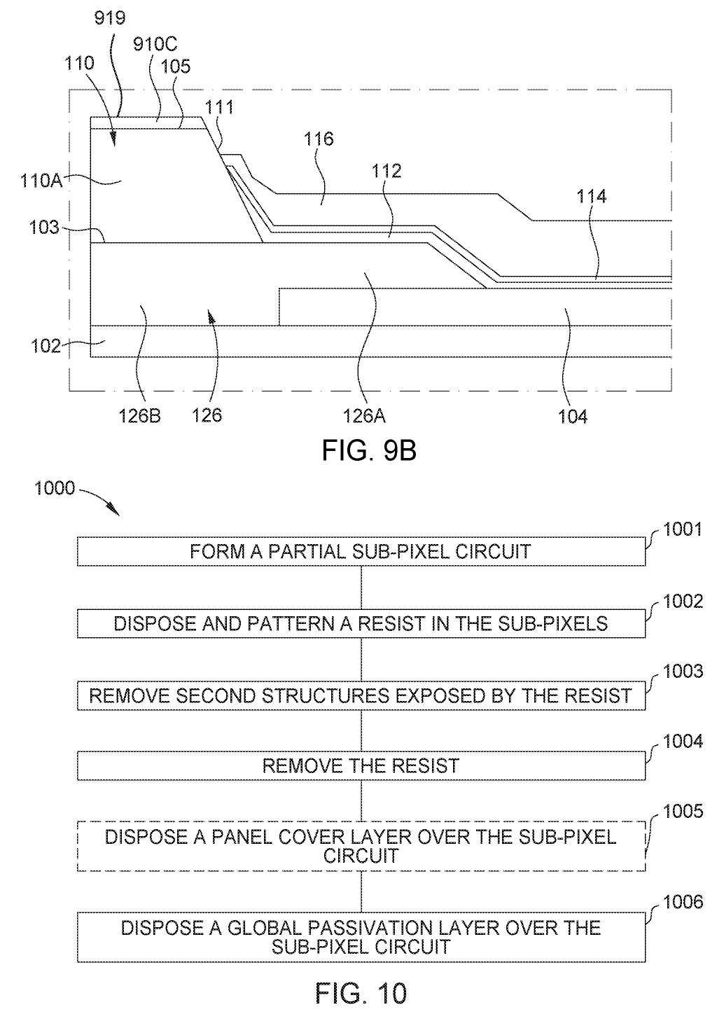

In some embodiments, which may be combined with other embodiments, the second structure 110B may also be disposed over an intermediate structure. The intermediate structure may be disposed over the upper surface 105 of the first structure 110A. The intermediate structure 910C (as shown in FIG. 9A and FIG. 9B) may be a protection layer. The protection layer may act as an etch stop layer to protect the first structure 110A from the etching process that is performed to remove the second structure 110B. In some examples, the intermediate structure 910C may include a silicon nitride (Si₃N₄), a silicon oxide (SiO₂), a silicon oxynitride (SiOₓN_{y}), or other dielectric material. In other examples, the intermediate structure 910C may include a metal material or TCO material. In some examples, the intermediate structure may be an anti-reflection coating.

The overhang extension 109A of the second structure 110B forms the overhang 109 and allows for the second structure 110B to shadow the first structure 110A. The shadowing of the overhang 109 provides for evaporation deposition of an OLED material 112 and a cathode 114. The OLED material 112 may include one or more of a HIL, a HTL, an EML, and an ETL. The OLED material 112 is disposed over and in contact with the anode 104. The OLED material 112 is disposed under adjacent overhangs 109 and may contact a sidewall 111 of the first structure 110A. In one embodiment, which may be combined with other embodiments, the OLED material 112 is different from the material of the first structure 110A and the second structure 110B. In examples including the intermediate structure, the OLED material 112 is different from the material of the first structure 110A, the second structure 110B, and the intermediate structure and the material of the cathode 114 is different from the material of the first structure 110A, the second structure 110B, and intermediate structure.

The cathode 114 is disposed over the OLED material 112 and extends under the adjacent overhangs 109. The cathode 114 may extend past an endpoint of the OLED material 112. The cathode 114 may contact the sidewall 111 of the first structure 110A. The pixel structures 110 and an evaporation angle set by an evaporation source define deposition angles, e.g., the pixel structures 110 provide for a shadowing effect during evaporation deposition with the evaporation angle set by the evaporation source. The cathode 114 includes a conductive material, such as a metal. E.g., the cathode 114 includes, but is not limited to, silver, magnesium, chromium, titanium, aluminum, ITO, or a combination thereof. In one embodiment, material of the cathode 114 is different from the material of the first structure 110A and the second structure 110B.

Each sub-pixel 106 includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the overhangs 109. In examples where there is no capping layer, the encapsulation layer 116 is disposed over the cathode 114 and extends at least to contact the cathode 114 over the sidewall 111 of the first structure 110A. In some embodiments, which may be combined with other embodiments, the encapsulation layer 116 extends past an endpoint of the cathode 114 to contact the sidewall 111 of the first structure 110A. The encapsulation layer 116 includes the non-conductive inorganic material, such as the silicon-containing material. The silicon-containing material may include Si₃N₄ containing materials.

After deposition of the OLED material 112, the cathode 114, and the encapsulation layer 116 (and, in some examples, the capping layers), the second structures 110B is removed from the sub-pixel circuit 100. As a result of the removal of the second structures 110B, encapsulation overhangs 116A remain on the sub-pixel circuit 100. The encapsulation overhangs 116A are formed from the encapsulation layer 116 that extends to contact the second structure 110B at an underside surface of the overhang extension 109A. The encapsulation overhangs 116A are defined by an encapsulation extension 117 of the encapsulation layer 116. The encapsulation overhang 116A is disposed over the separations structures, extends from a sidewall 111 of the first structure 110A, and defines a gap 118 between a portion of the encapsulation layer 116 disposed over the separation structure 126 and the encapsulation extension 117. An upper surface 117A of the encapsulation overhang 116A is coplanar with an upper surface 105 of the first structure 110A

By removing the second structure 110B, the viewing angle of the sub-pixel circuit 100 at ultra-high pixel per inch (PPI) is increased, as the second structure 110B may block the emission path of the light emitted by the sub-pixel. In addition, removal of the second structure decreases the amount of ambient reflection within the sub-pixel circuit 100. The second structures 110B may increase the amount of ambient light that is reflected off of the display. By removing the second structures 110B, and thus reducing the ambient reflection, the image contrast of the display may be increased.

In embodiments including one or more capping layers, which may be combined with other embodiments, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition.

A global layer is disposed over the sub-pixel circuit 100. The global layer includes at least one of panel cover layer 350 or a global passivation layer 120. In embodiments with the panel cover layer 350 and the global passivation layer 120, the global passivation layer 120 is disposed over the panel cover layer 350, as shown in FIG. 3M. In another embodiment, which may be combined with other embodiments, the global passivation layer 120 disposed over the pixel structure 110 and the encapsulation layer 116. The global passivation layer 120 is disposed on (e.g., contacts) the upper surface 105 of the first structure 110A and the upper surface 117A of the encapsulation overhang 116A. In yet another embodiment, the sub-pixel includes an intermediate passivation layer disposed over the pixel structures 110 of each of the sub-pixels 106 and disposed between the encapsulation layer 116 and the global passivation layer 120.

The panel cover layer 350 (as shown in FIG. 3L) is disposed over the sub-pixel circuit 100. The panel cover layer 350 includes TCO, metallic materials, or dielectric materials. For example, the panel cover layer 350 may include an indium-tin-oxide (ITO), an indium zinc oxide (IZO), silicon nitride, silicon oxide, or combinations thereof. The panel cover layer 350 is disposed on (e.g., contacts) the upper surface 105 of the first structure 110A and the upper surface 117A of the encapsulation overhang 116A. The global passivation layer 120 is disposed on (e.g., contacts) the panel cover layer 350. The panel cover layer 350 may be disposed globally over the sub-pixel circuit 100 to reduce the likelihood of moisture invasion at the interface of the encapsulation layer 116 and the first structure 110A.

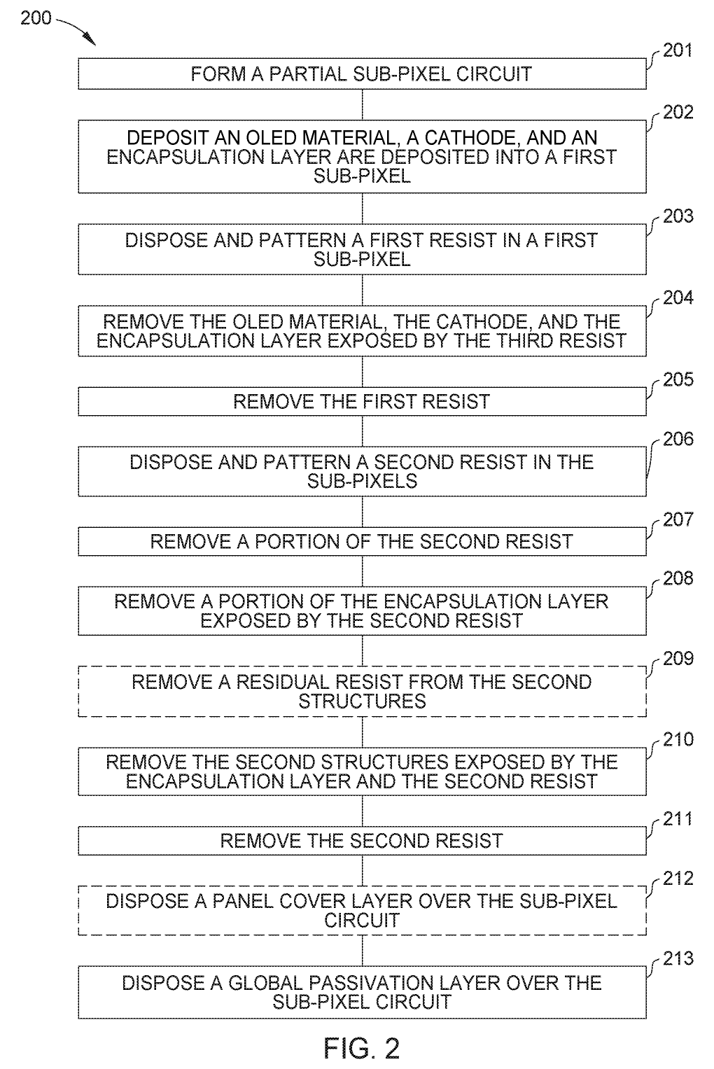

FIG. 2 is a flow diagram of a method 200 for forming a sub-pixel circuit 100. FIGS. 3A-3M are schematic, cross-sectional views of a substrate 102 during the method 200 for forming the sub-pixel circuit 100.

At operation 201, as shown in FIG. 3A, a partial sub-pixel circuit 300A is formed. A first structure 110A and a second structure 110B are deposited over a separation structure 126. The separation structure 126 includes a separation structure extension portion 126A and a separation structure body portion 126B. The separation structure extension portion 126A is disposed over an anode 104. The separation structure body portion 126B separates adjacent anodes 104. In one embodiment, the anode 104 is a metal-containing layer. The anode 104 is a layer stack of a first TCO layer, a second metal-containing layer disposed on the first TCO layer, and a third TCO layer disposed on the second metal-containing layer. The anode 104 is disposed on a substrate 102. The separation structure body portion 126B is disposed over substrate 102. In some examples, the separation structure body portion 126B is disposed on the substrate 102. The first structure 110A is disposed over the separation structure 126. The second structure 110B is disposed over the first structure 110A.

At operation 202, as shown in FIG. 3B, the OLED materials 112, the cathode 114, and the encapsulation layer 116 of the first sub-pixel 108A are deposited. The shadowing of the overhang 109 provides for evaporation deposition each of the OLED material 112, and a cathode 114. The pixel structures 110 and the evaporation angle set by the evaporation source define the angle of deposition. I.e., the pixel structures 110 provide for a shadowing effect during evaporation deposition with the evaporation angle set by the evaporation source configured to emit the deposition material at a particular angle with regard to the pixel structure 110.

The OLED material 112 is disposed over a sidewall 111 of the first structure 110A and the cathode 114 is disposed over the OLED material 112. In one example, the cathode extends past the OLED material 112 to contact the sidewall 111 of the first structure 110A of the pixel structures 110. The encapsulation layer 116 is deposited over the cathode 114. The encapsulation layer 116 is disposed over the cathode 114 that is disposed over the OLED material 112 on the sidewall 111 of the first structure 110A. In another example, the encapsulation layer 116 is disposed over the cathode 114. In another example, the encapsulation layer 116 extends past the cathode 114 to contact the sidewall 111 of the first structure 110A. In some examples, the encapsulation layer 116 extends to contact the second structure 110B at an underside surface of the overhang extension 109A. The encapsulation layer 116 extends over an upper surface 115 of the second structure 110B. In embodiments including capping layers, the capping layers are deposited between the cathode 114 and the encapsulation layer 116. The capping layers may be deposited by evaporation deposition.

In some examples, which may be combined with other embodiments, the OLED material 112 and the cathode 114 are disposed over a sidewall 113 of the second structure 110B of the pixel structures 110. In other embodiments, which may be combined with other embodiments, the OLED material 112 and the cathode 114 are disposed over the upper surface 115 of the second structure 110B of the pixel structures 110. In still other embodiments, which may be combined with other embodiments, the OLED material 112 and the cathode 114 end on the sidewall 111 of the first structure 110A, i.e., are not disposed over the sidewall 113 of the second structure 110B or the upper surface 115 of the second structure 110B.

In some embodiments, which may be combined with other embodiments, the encapsulation layer 116 extends to contact the second structure 110B at an underside surface of the overhang extension 109A and to be disposed over the OLED material 112 and the cathode 114 when the OLED material 112 and the cathode 114 are disposed over the sidewall 113 and upper surface 115 of the second structure 110B. In some embodiments, which may be combined with other embodiments, the encapsulation layer 116 ends at the sidewall 111 of the first structure 110A, i.e., is not disposed over the sidewall 113 of the second structure 110B, the upper surface 115 of the second structure 110B, or the underside surface of the overhang extension 109A of the pixel structures 110.

At operation 203, as shown in FIG. 3C, a resist 344 is disposed and patterned. The resist 344 is disposed in the first sub-pixel 108A. The resist 344 is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the resist 344 determines whether the resist 344 is a positive resist or a negative resist. The resist 344 is patterned to protect the first sub-pixel 108A from the subsequent etching processes. The patterning is one of a photolithography, digital lithography process, or laser ablation process.

At operation 204, as shown in FIG. 3D, portions of the OLED material 112, the cathode 114, and the encapsulation layer 116 exposed by the resist 344 are removed. The portions of the OLED material 112, the cathode 114, and the encapsulation layer 116 may be removed using dry etching, wet etching, or a combination of dry etching and wet etching. For example, portions of the OLED material 112 may be removed using ashing (e.g., O₂ ashing). In some examples, the encapsulation layer 116 that is not exposed by the resist 344 remains, while the OLED material 112 and the cathode 114 disposed on the upper surface 115 and sidewall 113 of the second structure 110B are removed. At operation 205, as shown in FIG. 3E, the resist 344 is removed.

Between operation 205 and operation 206, the operations 201-205 may be repeated to form the desired number of sub-pixels 106.

At operation 206, as shown in FIG. 3F, a resist 346 is disposed and patterned. The resist 346 is disposed in the sub-pixels 106 and over the pixel structures 110. The resist 346 is a positive resist or a negative resist. The chemical composition of the resist 346 determines whether the resist 346 is a positive resist or a negative resist. The resist 346 is patterned to protect the sub-pixels 106 from the subsequent etching processes. The patterning is one of a photolithography, digital lithography process, or laser ablation process.

At operation 207, as shown in FIG. 3G, a portion of the resist 346 is removed to expose a portion of the encapsulation layer 116. The resist 346 is removed using a photoresist ashing process. The photoresist ashing process may include using an oxygen (O₂) plasma, a fluorine (F₂) plasma, or a nitrogen/hydrogen plasma (N₂/H₂). The etch selectivity of the chemistry of the photoresist ashing process does not damage the encapsulation layer 116, thus enabling the encapsulation layer 116 to be exposed by the resist 346.

At operation 208, as shown in FIG. 3H, the portion of the encapsulation layer 116 that is exposed by the resist 346 is removed to expose the second structures 110B. The exposed portions of the encapsulation layer 116 are removed using a dry etching process. The dry etching may include a fluorine-based plasma etching, such as a CF₄ of SF₆ plasma etching. In some examples, a residual resist 346A remains on the upper surface 115 and a sidewall 113 of the second structure 110B. During the removal of the encapsulation layer 116, this residual resist 346A is protected by the encapsulation layer 116 and is not removed.

At optional operation 209, as shown in FIG. 3I, the residual resist 346A is removed from the second structures 110B. In some examples, the resist 346 is deposited on an upper surface 115 of the second structure 110B in the locations previously occupied by the OLED material 112. The residual resist 346A is removed using a photoresist ashing process.

At operation 210, as shown in FIG. 3J, the second structures 110B exposed by the encapsulation layer 116 and the resist 346 are removed to form an encapsulation overhang 116A. An upper surface 117A of the encapsulation overhang 116A is coplanar with an upper surface 105 of the first structure 110A. The second structures 110B may be removed using dry etching or wet etching. The wet etch may include an oxalic acid etch. The dry etch may include a chlorine-based etch for a metal material or fluorine-based etch for a dielectric material. In one example, if the second structure 110B is a TCO material or a metal material and the first structure 110A is a molybdenum or aluminum material, the second structure may be removed using an oxalic acid wet etch without damaging the first structure 110A.

At operation 211, as shown in FIG. 3K, the resist 346 is removed from the sub-pixels 106. At optional operation 212, as shown in FIG. 3L, a panel cover layer 350 is disposed over the sub-pixel circuit 100. The panel cover layer 350 is disposed on the upper surface 117A of the encapsulation overhang 116A and the upper surface of the first structure 110A. The panel cover layer 350 includes TCO, metallic materials, or dielectric materials. For example, the panel cover layer 350 may include an indium-tin-oxide (ITO), an indium zinc oxide (IZO), silicon nitride, silicon oxide, or combinations thereof. The panel cover layer 350 may be disposed globally over the sub-pixel circuit 100 to reduce the likelihood of moisture invasion at the interface of the encapsulation layer 116 and the first structure 110A.

At operation 213, as shown in FIG. 3M, a global passivation layer 120 is disposed over the sub-pixel circuit 100. In some embodiments, the global passivation layer 120 is disposed on the upper surface 117A of the encapsulation overhang 116A and the upper surface of the first structure 110A. In embodiments with the panel cover layer 350, the global passivation layer 120 is disposed on the panel cover layer 350.

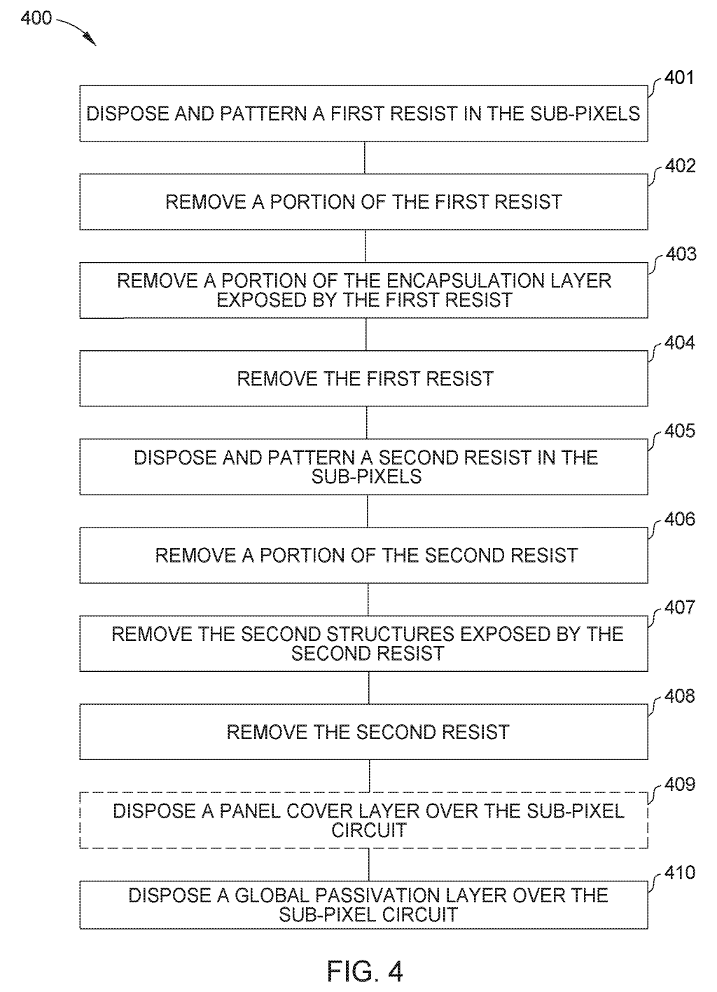

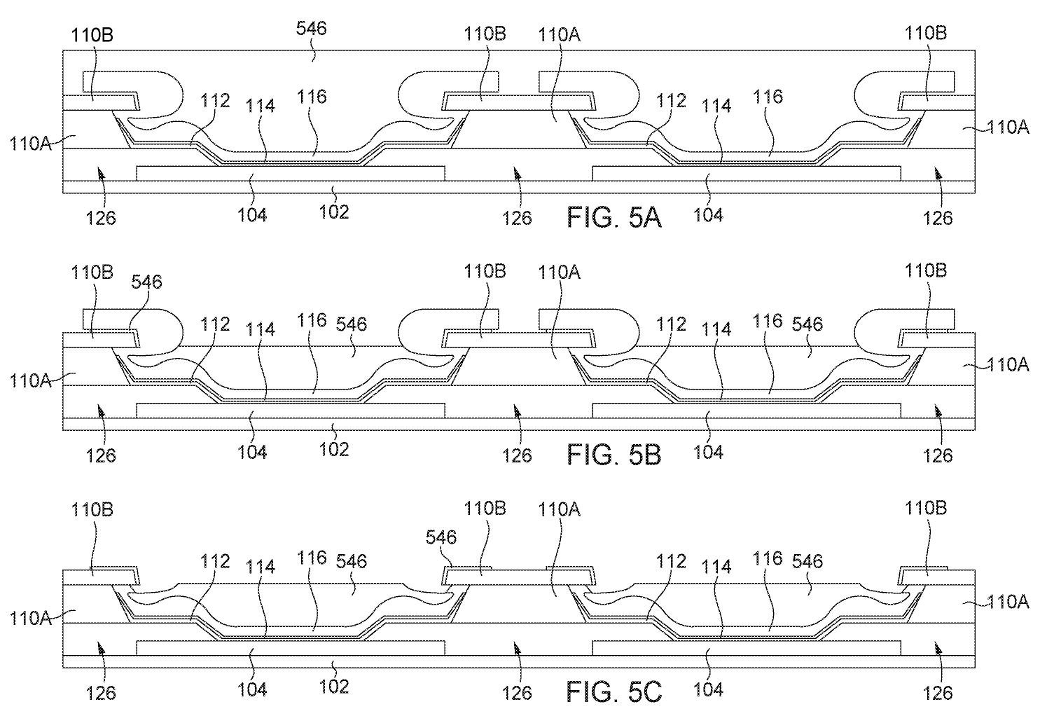

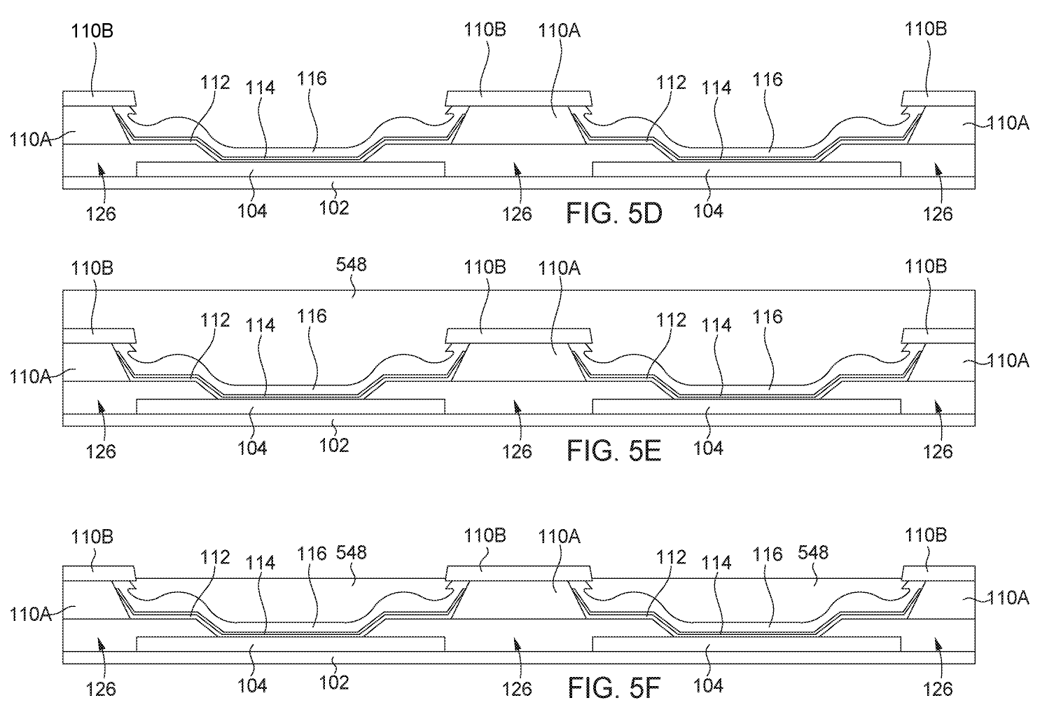

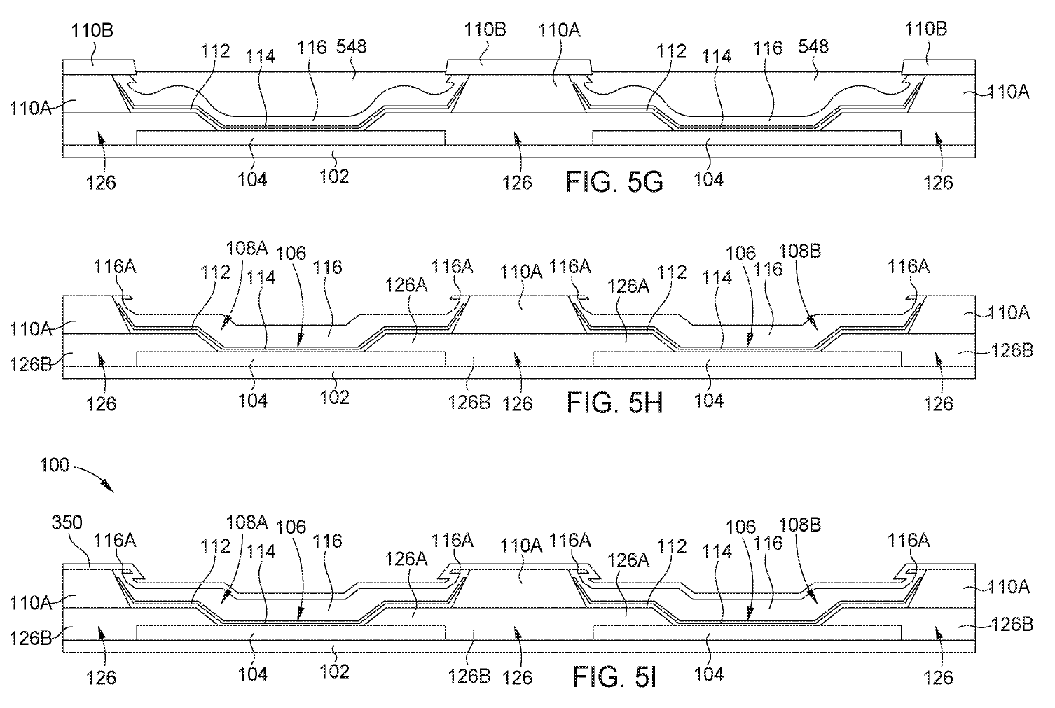

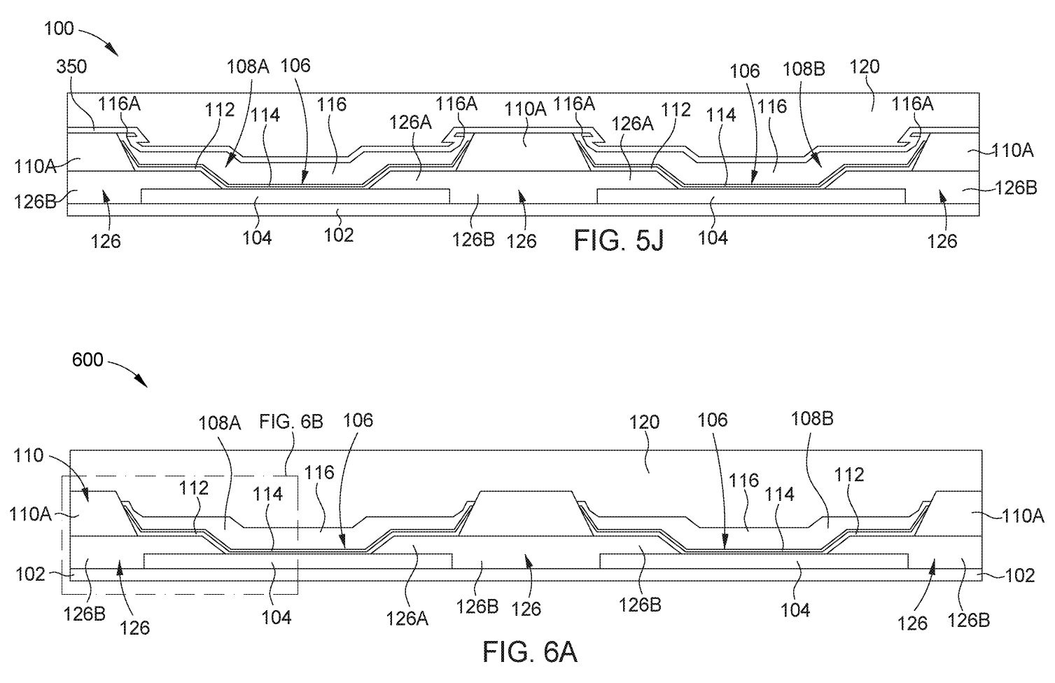

FIG. 4 is a flow diagram of a method 400 for forming a sub-pixel circuit 100. FIGS. 5A-5J are schematic, cross-sectional views of a substrate 102 during the method 400 for forming the sub-pixel circuit 100. The method 400 includes operations 201-205 and commences after the completion of operations 201-205. As previously noted, the operations 201-205 may be repeated to form the desired number of sub-pixels 106.

At operation 401, as shown in FIG. 5A, a resist 546 is disposed and patterned. The resist 546 is disposed in the sub-pixels 106 and over the pixel structures 110. The resist 546 is a positive resist or a negative resist. The chemical composition of the resist 546 determines whether the resist 546 is a positive resist or a negative resist. The resist 546 is patterned to protect the sub-pixels 106 from the subsequent etching processes. The patterning is one of a photolithography, digital lithography process, or laser ablation process.

At operation 402, as shown in FIG. 5B, a portion of the resist 546 is removed to expose a portion of the encapsulation layer 116. The resist 546 is removed using a photoresist ashing process. The photoresist ashing process may include using an oxygen (O₂) plasma, a fluorine (F₂) plasma, or a nitrogen/hydrogen plasma (N₂/H₂). The etch selectivity of the chemistry of the photoresist ashing process does not damage the encapsulation layer 116, thus enabling the encapsulation layer 116 to be exposed by the resist 546.

At operation 403, as shown in FIG. 5C, the portion of the encapsulation layer 116 that is exposed by the resist 546 is removed to expose the second structures 110B. The exposed portions of the encapsulation layer 116 are removed using a dry etching process, wet etching, or a combination of dry etching and wet etching. At operation 404, as shown in FIG. 5D, the resist 546 is removed from the sub-pixels 106.

At operation 405, as shown in FIG. 5E, a resist 548 is disposed and patterned. The resist 548 is disposed in the sub-pixels 106 and over the pixel structures 110. The resist 548 is a positive resist or a negative resist. The chemical composition of the resist 548 determines whether the resist 548 is a positive resist or a negative resist. The resist 548 is patterned to protect the sub-pixels 106 from the subsequent etching processes. The patterning is one of a photolithography, digital lithography process, or laser ablation process. The resist 548 is disposed within the sub-pixels 106 to provide protection for the encapsulation layer 116 disposed in the sub-pixels 106 from the etching process that is used to remove the second structures 110B.

At operation 406, as shown in FIG. 5F, a portion of the resist 548 is removed to expose the second structure 110B. The resist 548 is removed using a photoresist ashing process.

At operation 407, as shown in FIG. 5G, the second structures 110B exposed by the resist 548 are removed to form an encapsulation overhang 116A. An upper surface 117A of the encapsulation overhang 116A is coplanar with an upper surface 105 of the first structure 110A. The second structures 110B may be removed using dry etching or wet etching. The wet etch may include an oxalic acid etch. The dry etch may include a chlorine-based etch for a metal material or fluorine-based etch for a dielectric material. In one example, if the second structure 110B is a TCO material or a metal material and the first structure 110A is a molybdenum or aluminum material, the second structure may be removed using an oxalic acid wet etch without damaging the first structure 110A.

At operation 408, as shown in FIG. 5H, the resist 548 is removed from the sub-pixels 106. At optional operation 409, as shown in FIG. 5I, a panel cover layer 350 is disposed over the sub-pixel circuit 100. The panel cover layer 350 is disposed on the upper surface 117A of the encapsulation overhang 116A and the upper surface of the first structure 110A. The panel cover layer 350 includes TCO, metallic materials, or dielectric materials. For example, the panel cover layer 350 may include an indium-tin-oxide (ITO), an indium zinc oxide (IZO), silicon nitride, silicon oxide, or combinations thereof. The panel cover layer 350 may be disposed globally over the sub-pixel circuit 100 to reduce the likelihood of moisture invasion at the interface of the encapsulation layer 116 and the first structure 110A.

At operation 410, as shown in FIG. 5J, a global passivation layer 120 is disposed over the sub-pixel circuit 100. In some embodiments, the global passivation layer 120 is disposed on the upper surface 117A of the encapsulation overhang 116A and the upper surface of the first structure 110A. In embodiments with the panel cover layer 350, the global passivation layer 120 is disposed on the panel cover layer 350.

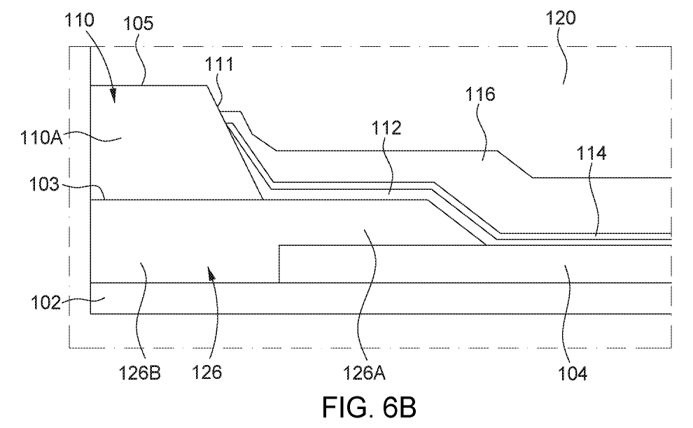

FIG. 6A is a schematic, cross-sectional view of a sub-pixel circuit 600 without the encapsulation overhangs 116A. FIG. 6B is a portion of the schematic, cross-sectional view of a portion of the sub-pixel circuit 600. The sub-pixel circuit 600 can be used in place of the sub-pixel circuit 100.

After deposition of the OLED material 112, the cathode 114, and the encapsulation layer 116 (and, in some examples, the capping layers), the second structures 110B are removed from the sub-pixel circuit 600. By removing the second structure 110B, the viewing angle of the sub-pixel circuit 600 at ultra-high pixel per inch (PPI) is increased. In addition, removal of the second structure decreases the amount of ambient reflection within the sub-pixel circuit 600.

A global layer is disposed over the sub-pixel circuit 600. The global layer is a panel cover layer 850 or the global passivation layer 120. In another embodiment, which may be combined with other embodiments, the global passivation layer 120 disposed over the pixel structure 110 and the encapsulation layer 116. The global passivation layer 120 is disposed on (e.g., contacts) the upper surface 105 of the first structure 110A. In yet another embodiment, the sub-pixel includes an intermediate passivation layer disposed over the pixel structures 110 of each of the sub-pixels 106 and disposed between the encapsulation layer 116 and the global passivation layer 120.

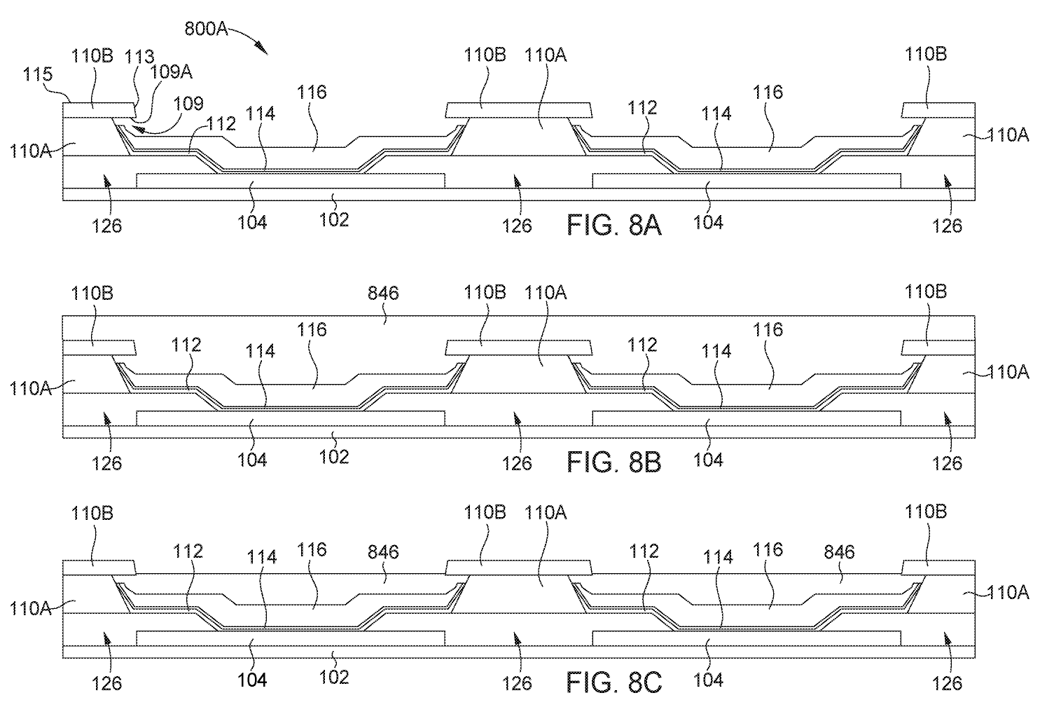

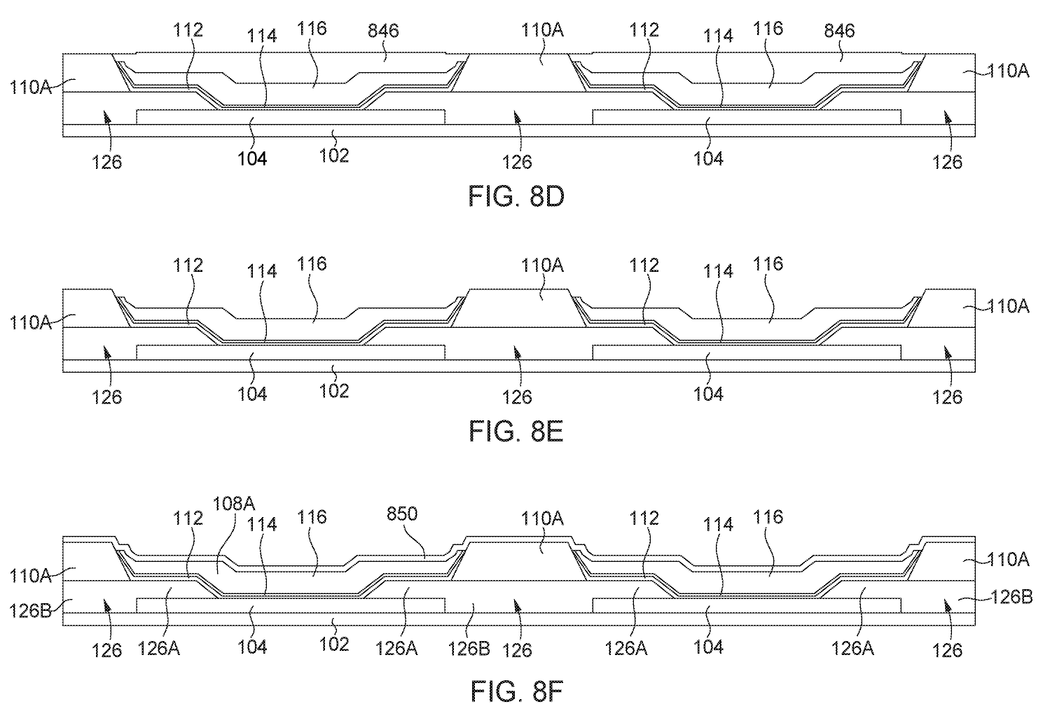

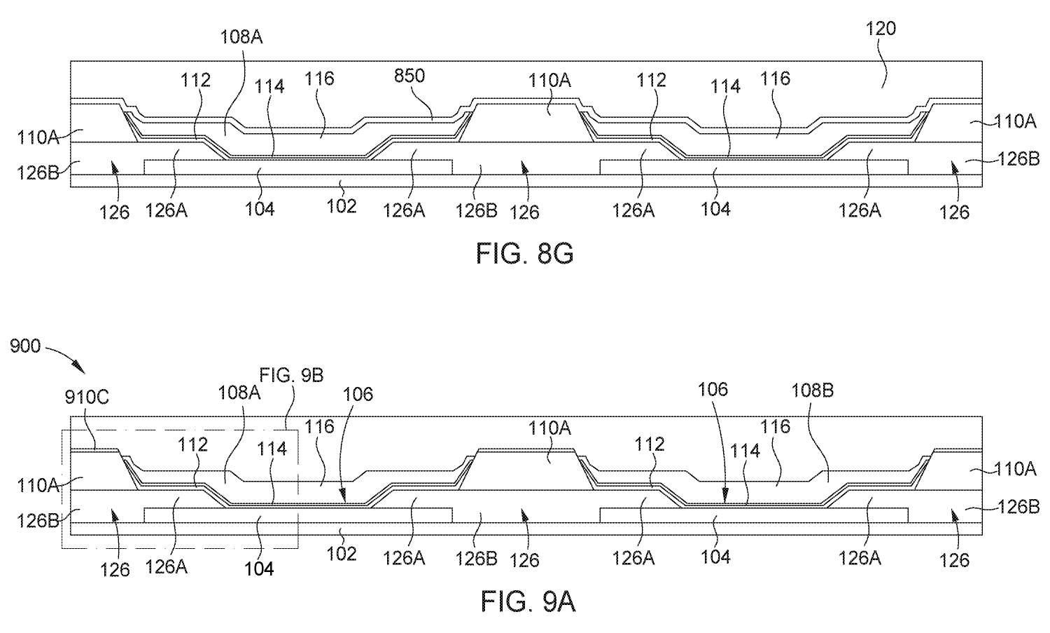

The panel cover layer 850 (as shown in FIG. 8F) is disposed over the sub-pixel circuit 600. The panel cover layer 850 includes TCO, metallic materials, or dielectric materials. For example, the panel cover layer 850 may include an indium-tin-oxide (ITO), an indium zinc oxide (IZO), silicon nitride, silicon oxide, or combinations thereof. The panel cover layer 850 is disposed on (e.g., contacts) the upper surface 105 of the first structure 110A. The global passivation layer 120 is disposed on (e.g., contacts) the panel cover layer 850. The panel cover layer 850 may be disposed globally over the sub-pixel circuit 600 to reduce the likelihood of moisture invasion at the interface of the encapsulation layer 116 and the first structure 110A.

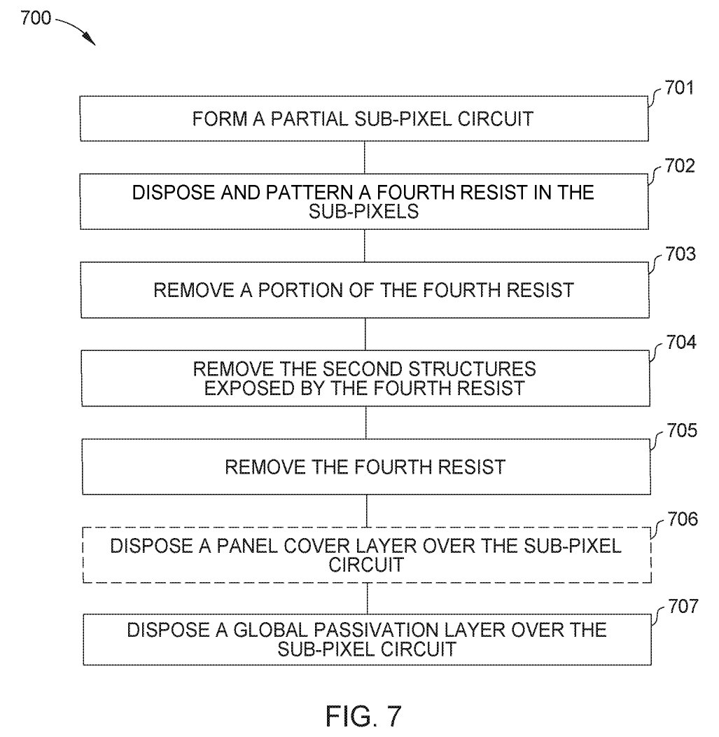

FIG. 7 is a flow diagram of a method 700 for forming a sub-pixel circuit 600. FIGS. 8A-8G are schematic, cross-sectional views of a substrate 102 during the method 700 for forming the sub-pixel circuit 600.

At operation 701, as shown in FIG. 8A, a partial sub-pixel circuit 800A is formed The OLED material 112, the cathode 114, and the encapsulation layer 116 are removed from the upper surface 115, the sidewall 113, and the underside surface of the overhang extension 109A of the second structure 110B. The portions of the OLED material 112, the cathode 114, and the encapsulation layer 116 may be removed may be removed using dry etching, wet etching, or a combination of dry etching and wet etching. For example, portions of the OLED material 112 may be removed using ashing (e.g., O₂ ashing). As a result of the removal of the OLED material 112, the cathode 114, and the encapsulation layer 116 from the upper surface 115, the sidewall 113, and the underside surface of the overhang extension 109A of the second structure 110B, no encapsulation overhangs 116A, as shown in sub-pixel circuit 600, remain on the sub-pixel circuit 600 after the removal of the second structure 110B. At operation 702, as shown in FIG. 8B, a resist 846 is disposed and patterned. The resist 846 is disposed in the sub-pixels 106 and over the pixel structures 110. The resist 846 is a positive resist or a negative resist. The chemical composition of the resist 846 determines whether the resist 846 is a positive resist or a negative resist. The resist 846 is patterned to protect the sub-pixels 106 from the subsequent etching processes. The patterning is one of a photolithography, digital lithography process, or laser ablation process.

At operation 703, as shown in FIG. 8C, a portion of the resist 846 is removed to expose the second structures 110B. The resist 846 is removed using a photoresist ashing process. The photoresist ashing process may include using an oxygen (O₂) plasma, a fluorine (F₂) plasma, or a nitrogen/hydrogen plasma (N₂/H₂). The etch selectivity of the chemistry of the photoresist ashing process does not damage the encapsulation layer 116, thus enabling the encapsulation layer 116 to be exposed by the resist 846.

At operation 704, as shown in FIG. 8D, the second structures 110B exposed by the resist 846 are removed. The second structures 110B may be removed using dry etching or wet etching. The wet etch may include an oxalic acid etch. The dry etch may include a chlorine-based etch for a metal material or fluorine-based etch for a dielectric material. In one example, if the second structure 110B is a TCO material or a metal material and the first structure 110A is a molybdenum or aluminum material, the second structure may be removed using an oxalic acid wet etch without damaging the first structure 110A.

At operation 705, as shown in FIG. 8E, the resist 846 is removed from the sub-pixels 106. At optional operation 706, as shown in FIG. 8F, a panel cover layer 850 is disposed over the sub-pixel circuit 600. The panel cover layer 850 is disposed on the upper surface of the first structure 110A. The panel cover layer 850 includes TCO, metallic materials, or dielectric materials. For example, the panel cover layer 850 may include an indium-tin-oxide (ITO), an indium zinc oxide (IZO), silicon nitride, silicon oxide, or combinations thereof. The panel cover layer 850 may be disposed globally over the sub-pixel circuit 600 to reduce the likelihood of moisture invasion at the interface of the encapsulation layer 116 and the first structure 110A.

At operation 707, as shown in FIG. 8G, a global passivation layer 120 is disposed over the sub-pixel circuit 600. In some embodiments, the global passivation layer 120 is disposed on the upper surface of the first structure 110A. In embodiments with the panel cover layer 850, the global passivation layer 120 is disposed on the panel cover layer 850.

FIG. 9A is a schematic, cross-sectional view of a sub-pixel circuit 900 with intermediate structure 910C. FIG. 9B is a portion of the schematic, cross-sectional view of a portion of the sub-pixel circuit 900. The sub-pixel circuit 900 can be used in place of the sub-pixel circuit 100.

In some embodiments, which may be combined with other embodiments, the second structure 110B may also be disposed over an intermediate structure 910C. The intermediate structure 910C may be disposed over the upper surface 105 of the first structure 110A. The intermediate structure 910C may be a protection layer. The protection layer may act as an etch stop layer to protect the first structure 110A from the etching process that is performed to remove the second structure 110B. The intermediate structure 910C may include a silicon nitride (Si₃N₄), a silicon oxide (SiO₂), a silicon oxynitride (SiOₓN_{y}), or other dielectric material. In other examples, the intermediate structure 910C may include a metal material or TCO material. In some examples, the intermediate structure may be an anti-reflection coating.

In one embodiment, which may be combined with other embodiments, the OLED material 112 is different from the material of the first structure 110A, the second structure 110B, and the intermediate structure 910C. In one embodiment, material of the cathode 114 is different from the material of the first structure 110A, the second structure 110B, and intermediate structure 910C.

A global layer is disposed over the sub-pixel circuit 900. The global layer is a panel cover layer 1150 or the global passivation layer 120. In another embodiment, which may be combined with other embodiments, the global passivation layer 120 disposed over the pixel structure 110 and the encapsulation layer 116. The global passivation layer 120 is disposed on (e.g., contacts) an upper surface 919 of the intermediate structure 910C. In yet another embodiment, the sub-pixel circuit 900 includes an intermediate passivation layer disposed over the pixel structures 110 of each of the sub-pixels 106 and disposed between the encapsulation layer 116 and the global passivation layer 120.

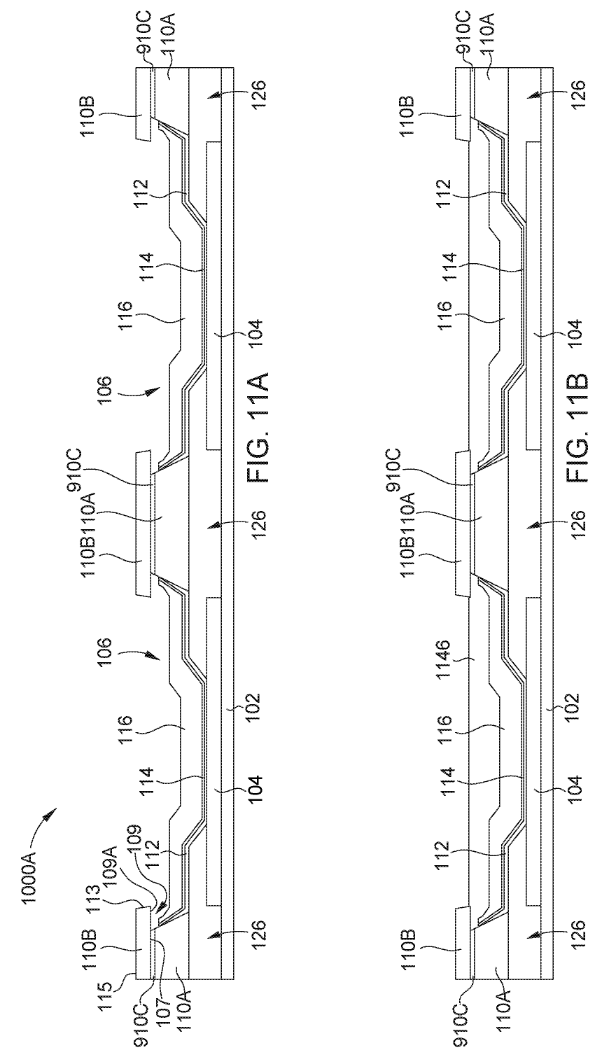

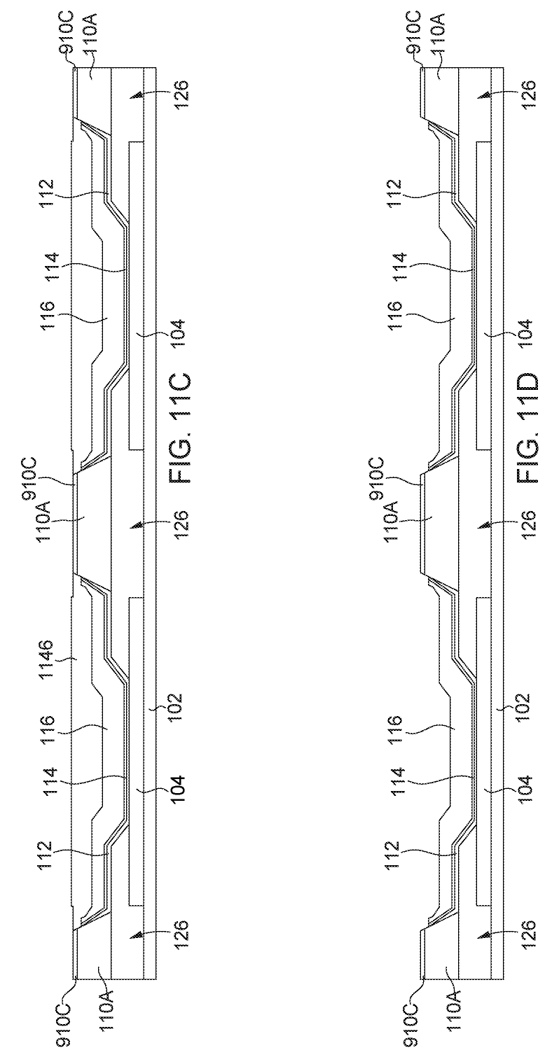

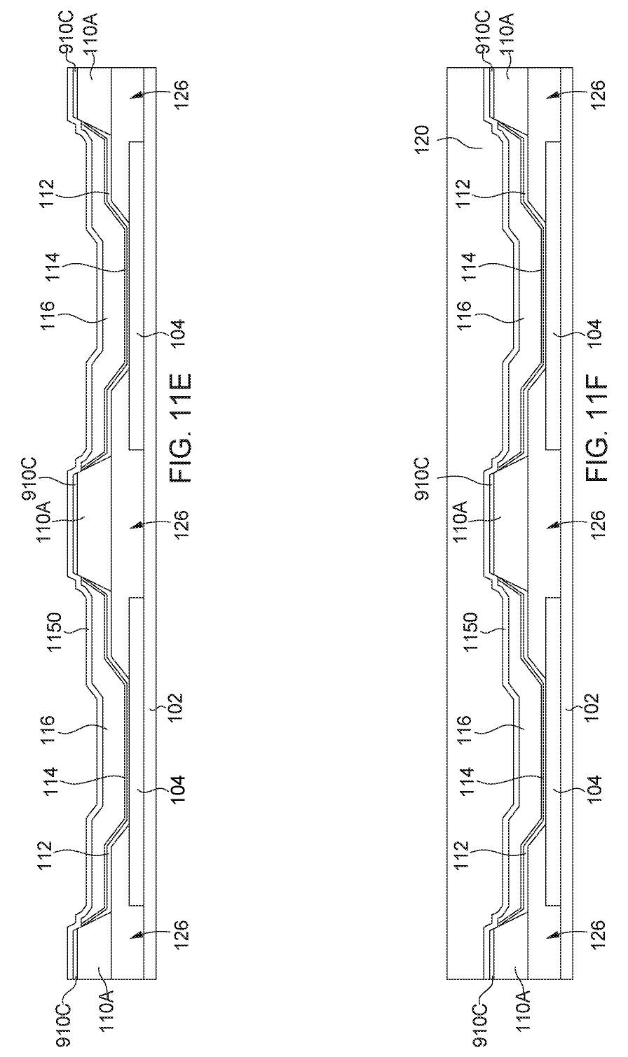

The panel cover layer 1150 (as shown in FIG. 11E) is disposed over the sub-pixel circuit 900. The panel cover layer 1150 includes TCO, metallic materials, or dielectric materials. For example, the panel cover layer 1150 may include an indium-tin-oxide (ITO), an indium zinc oxide (IZO), silicon nitride, silicon oxide, or combinations thereof. The panel cover layer 1150 is disposed on (e.g., contacts) the upper surface 919 of the intermediate structure 910C. The global passivation layer 120 is disposed on (e.g., contacts) the panel cover layer 1150. The panel cover layer 1150 may be disposed globally over the sub-pixel circuit 900 to reduce the likelihood of moisture invasion at the interface of the encapsulation layer 116 and the first structure 110A.

FIG. 10 is a flow diagram of a method 1000 for forming a sub-pixel circuit 900. FIGS. 11A-11F are schematic, cross-sectional views of a substrate 102 during the method 1000 for forming the sub-pixel circuit 900.

At operation 1001, as shown in FIG. 11A, a partial sub-pixel circuit 1000A is formed. A first structure 110A and a second structure 110B are deposited over a separation structure 126. The separation structure 126 includes a separation structure extension portion 126A and a separation structure body portion 126B. The separation structure extension portion 126A is disposed over an anode 104. The separation structure body portion 126B separates adjacent anodes 104. In one embodiment, the anode 104 is a metal-containing layer. The anode 104 is a layer stack of a first TCO layer, a second metal-containing layer disposed on the first TCO layer, and a third TCO layer disposed on the second metal-containing layer. The anode 104 is disposed on a substrate 102. The separation structure body portion 126B is disposed over substrate 102. In some examples, the separation structure body portion 126B is disposed on the substrate 102.

The first structure 110A is disposed over the separation structure 126. The second structure 110B is disposed over an intermediate structure 910C. The intermediate structure 910C is disposed over the first structure 110A. The intermediate structure 910C may be a protection layer. The protection layer may act as an etch stop layer to protect the first structure 110A from the etching process that is performed to remove the second structure 110B. The intermediate structure 910C may include a silicon nitride (Si₃N₄), a silicon oxide (SiO₂), a silicon oxynitride (SiOₓN_{y}), or other dielectric material. In other embodiments, the intermediate structure 910C is a TCO material or a metal material. In some examples, the intermediate structure may be an anti-reflection coating.

An OLED material 112, a cathode 114, and an encapsulation layer 116 are deposited in the sub-pixels 106. The shadowing of the overhang 109 provides for evaporation deposition each of the OLED material 112, and a cathode 114. The pixel structures 110 and the evaporation angle set by the evaporation source define the angle of deposition. I.e., the pixel structures 110 provide for a shadowing effect during evaporation deposition with the evaporation angle set by the evaporation source configured to emit the deposition material at a particular angle with regard to the pixel structure 110.

The OLED material 112 is disposed over a sidewall 111 of the first structure 110A and the cathode 114 is disposed over the OLED material 112. In one example, the cathode extends past the OLED material 112 to contact the sidewall 111 of the first structure 110A of the pixel structures 110. The encapsulation layer 116 is deposited over the cathode 114. The encapsulation layer 116 is disposed over the cathode 114 that is disposed over the OLED material 112 on the sidewall 111 of the first structure 110A. In another example, the encapsulation layer 116 extends past the cathode 114 to contact the sidewall 111 of the first structure 110A. In some examples, the encapsulation layer 116 extends to contact the second structure 110B at an underside surface of the overhang extension 109A. The encapsulation layer 116 extends over an upper surface 115 of the second structure 110B. In embodiments including capping layers, the capping layers are deposited between the cathode 114 and the encapsulation layer 116. The capping layers may be deposited by evaporation deposition.

In some examples, which may be combined with other embodiments, the OLED material 112 and the cathode 114 are disposed over a sidewall 113 of the second structure 110B of the pixel structures 110. In other embodiments, which may be combined with other embodiments, the OLED material 112 and the cathode 114 are disposed over the upper surface 115 of the second structure 110B of the pixel structures 110. In still other embodiments, which may be combined with other embodiments, the OLED material 112 and the cathode 114 end on the sidewall 111 of the first structure 110A, i.e., are not disposed over the sidewall 113 of the second structure 110B or the upper surface 115 of the second structure 110B.

In some embodiments, which may be combined with other embodiments, the encapsulation layer 116 extends to contact the second structure 110B at an underside surface of the overhang extension 109A and to be disposed over the OLED material 112 and the cathode 114 when the OLED material 112 and the cathode 114 are disposed over the sidewall 113 and upper surface 115 of the second structure 110B. In some embodiments, which may be combined with other embodiments, the encapsulation layer 116 ends at the sidewall 111 of the first structure 110A, i.e., is not disposed over the sidewall 113 of the second structure 110B, the upper surface 115 of the second structure 110B, or the underside surface of the overhang extension 109A of the pixel structures 110.

At operation 1002, as shown in FIG. 11B, a resist 1146 is disposed and patterned. The resist 1146 is disposed in the sub-pixels 106 and over the pixel structures 110. The resist 1146 is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the resist 1146 determines whether the resist 1146 is a positive resist or a negative resist. The resist 1146 is patterned to protect the sub-pixels 106 from the subsequent etching processes. The patterning is one of a photolithography, digital lithography process, or laser ablation process.

At operation 1003, as shown in FIG. 11C, the second structures 110B exposed by the resist 1146 are removed. The second structures 110B may be removed using dry etching or wet etching. The wet etch may include an oxalic acid etch. The dry etch may include a chlorine-based etch for a metal material or fluorine-based etch for a dielectric material. In one example, if the second structure 110B is a TCO material or a metal material and the first structure 110A is a molybdenum or aluminum material, the second structure may be removed using an oxalic acid wet etch without damaging the first structure 110A.

At operation 1004, as shown in FIG. 11D, the resist 1146 is removed from the sub-pixels 106. At optional operation 1005, as shown in FIG. 11E, a panel cover layer 1150 is disposed over the sub-pixel circuit 900. The panel cover layer 1150 is disposed on the upper surface 919 of the intermediate structure 910C. The panel cover layer 1150 includes TCO, metallic materials, or dielectric materials. For example, the panel cover layer 1150 may include an indium-tin-oxide (ITO), an indium zinc oxide (IZO), silicon nitride, silicon oxide, or combinations thereof. The panel cover layer 1150 may be disposed globally over the sub-pixel circuit 900 to reduce the likelihood of moisture invasion at the interface of the encapsulation layer 116 and the first structure 110A.

At operation 1006, as shown in FIG. 11F, a global passivation layer 120 is disposed over the sub-pixel circuit 900. In some embodiments, the global passivation layer 120 is disposed on the upper surface 919 of the intermediate structure 910C. In embodiments with the panel cover layer 1150, the global passivation layer 120 is disposed on the panel cover layer 1150.

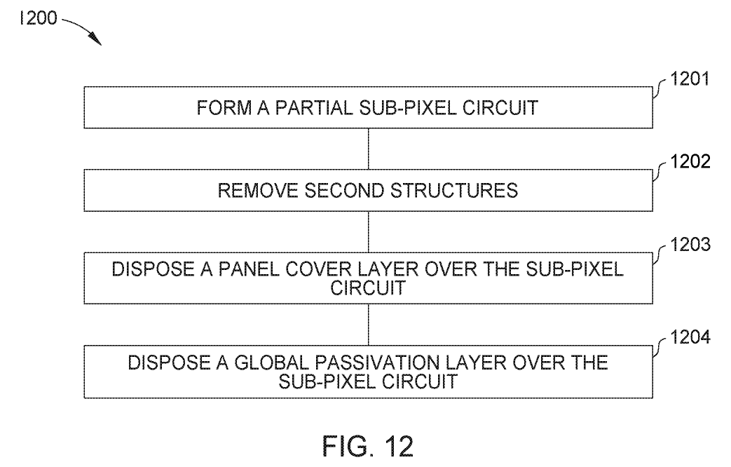

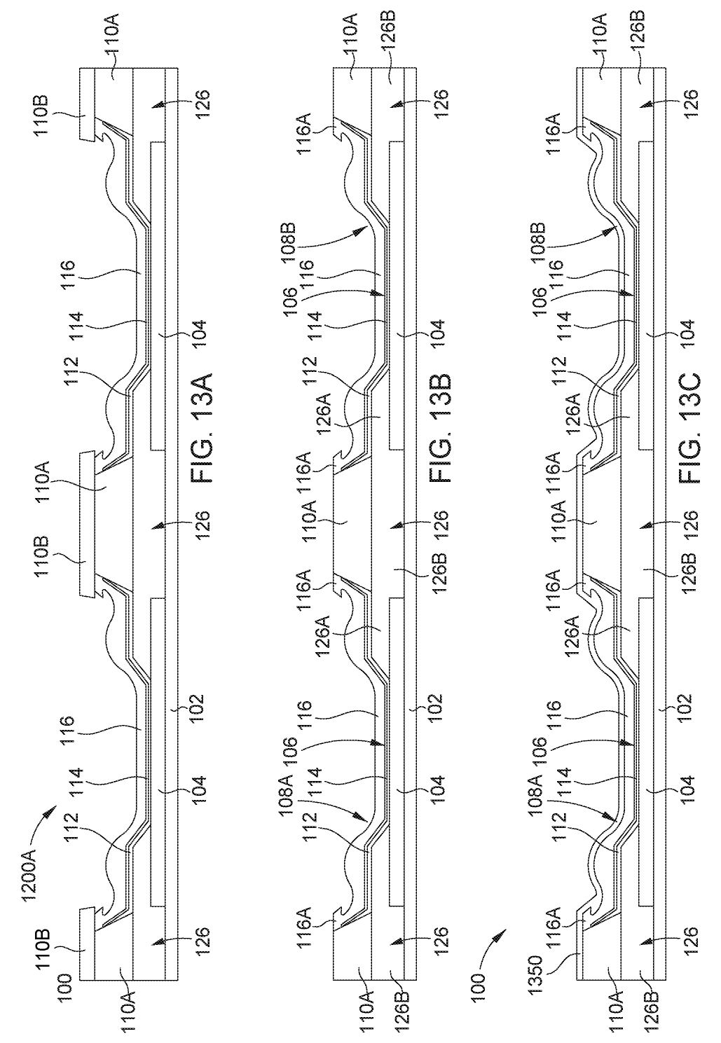

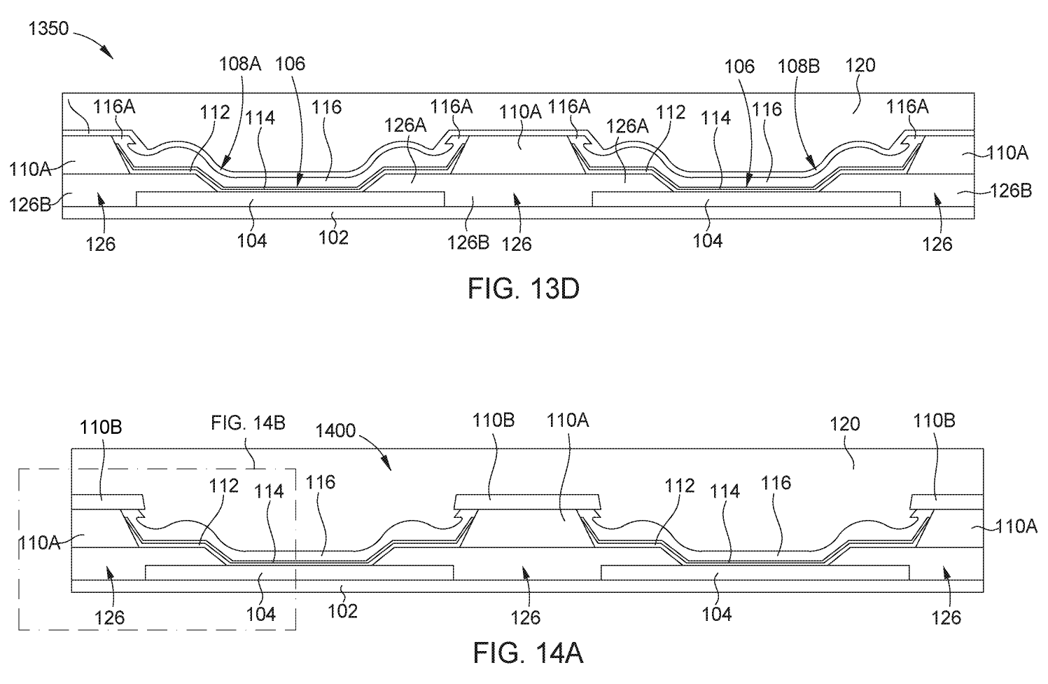

FIG. 12 is a flow diagram of a method 1200 for forming a sub-pixel circuit 900. FIGS. 13A-13D are schematic, cross-sectional views of a substrate 102 during the method 1200 for forming the sub-pixel circuit 900. At operation 1201, a partial sub-pixel circuit 1200A is formed.

At operation 1202, as shown in FIG. 13B, the second structures 110B are removed to form an encapsulation overhang 116A. An upper surface 117A of the encapsulation overhang 116A is coplanar with an upper surface 105 of the first structure 110A. The second structures 110B may be removed using wet etching. The wet etch may include an oxalic acid etch. The dry etch may include a chlorine-based etch for a metal material or fluorine-based etch for a dielectric material. In one example, if the second structure 110B is a TCO material or a metal material and the first structure 110A is a molybdenum or aluminum material, the second structure may be removed using an oxalic acid wet etch without damaging the first structure 110A.

Using method 1200, additional photoresist depositions operations are not required due to the etch selectivity of the wet etching process. The wet etching process enables the removal of the second structure without damaging the first structure 110A or the encapsulation layer 116. In some examples, the sub-pixel circuit 900 includes an intermediate structure disposed between the first structure 110A and the second structure 110B. The intermediate structure may be a protection layer. The protection layer may act as an etch stop layer to protect the first structure 110A from the etching process that is performed to remove the second structure 110B. The intermediate structure may include a silicon nitride (Si₃N₄), a silicon oxide (SiO₂), a silicon oxynitride (SiOₓN_{y}), or other dielectric material. In some examples, the intermediate structure may be an anti-reflection coating.

At operation 1203, as shown in FIG. 13C, a panel cover layer 1350 is disposed over the sub-pixel circuit 900. The panel cover layer 1350 is disposed on the upper surface 117A of the encapsulation overhang 116A and the upper surface of the first structure 110A. The panel cover layer 1350 includes TCO, metallic materials, or dielectric materials. For example, the panel cover layer 1350 may include an indium-tin-oxide (ITO), an indium zinc oxide (IZO), silicon nitride, silicon oxide, or combinations thereof. The panel cover layer 1350 may be disposed globally over the sub-pixel circuit 900 to reduce the likelihood of moisture invasion at the interface of the encapsulation layer 116 and the first structure 110A.

At operation 1204, as shown in FIG. 13D, a global passivation layer 120 is disposed over the sub-pixel circuit 900. In some embodiments, the global passivation layer 120 is disposed on the upper surface 117A of the encapsulation overhang 116A and the upper surface of the first structure 110A. In embodiments with the panel cover layer 1350, the global passivation layer 120 is disposed on the panel cover layer 1350.

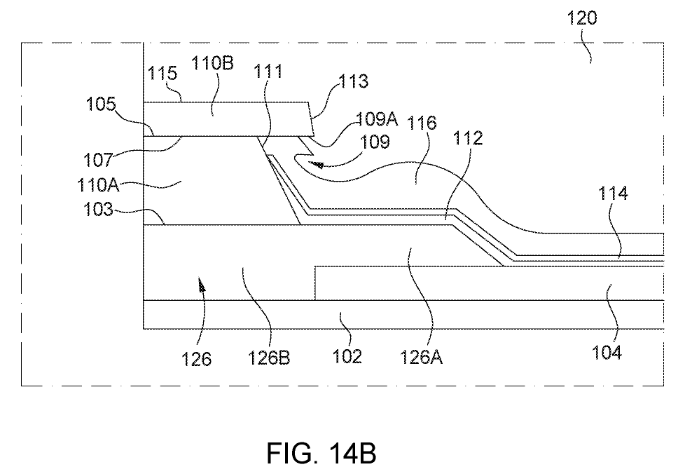

FIG. 14A is a schematic, cross-sectional view of a sub-pixel circuit 1400 with second structures 110B. FIG. 14B is a portion of the schematic, cross-sectional view of a portion of the sub-pixel circuit 1400. The sub-pixel circuit 1400 can be used in place of the sub-pixel circuit 100.

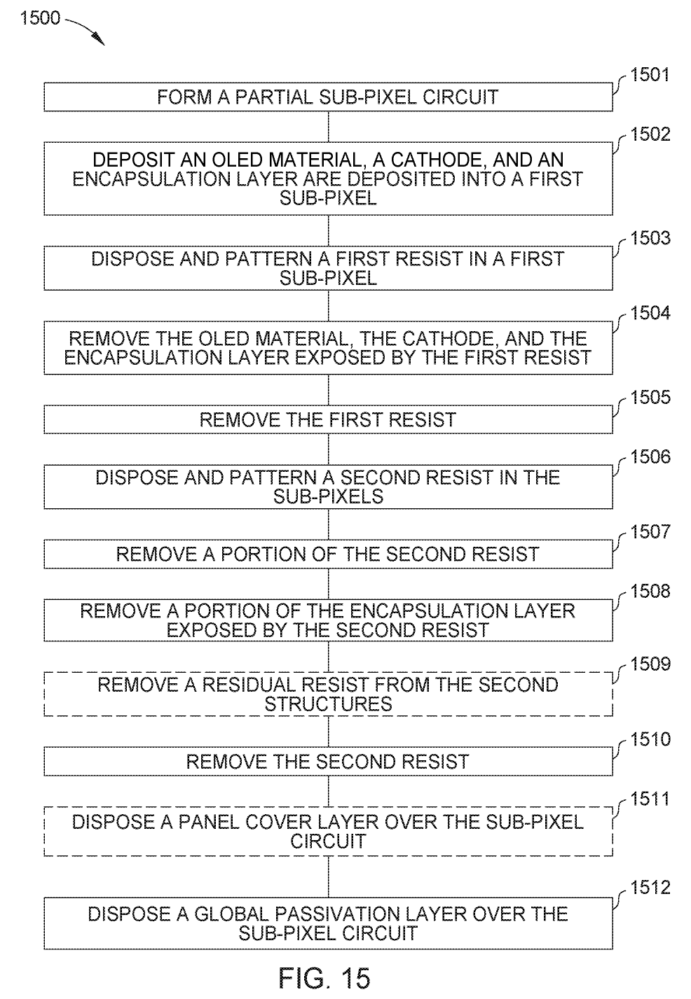

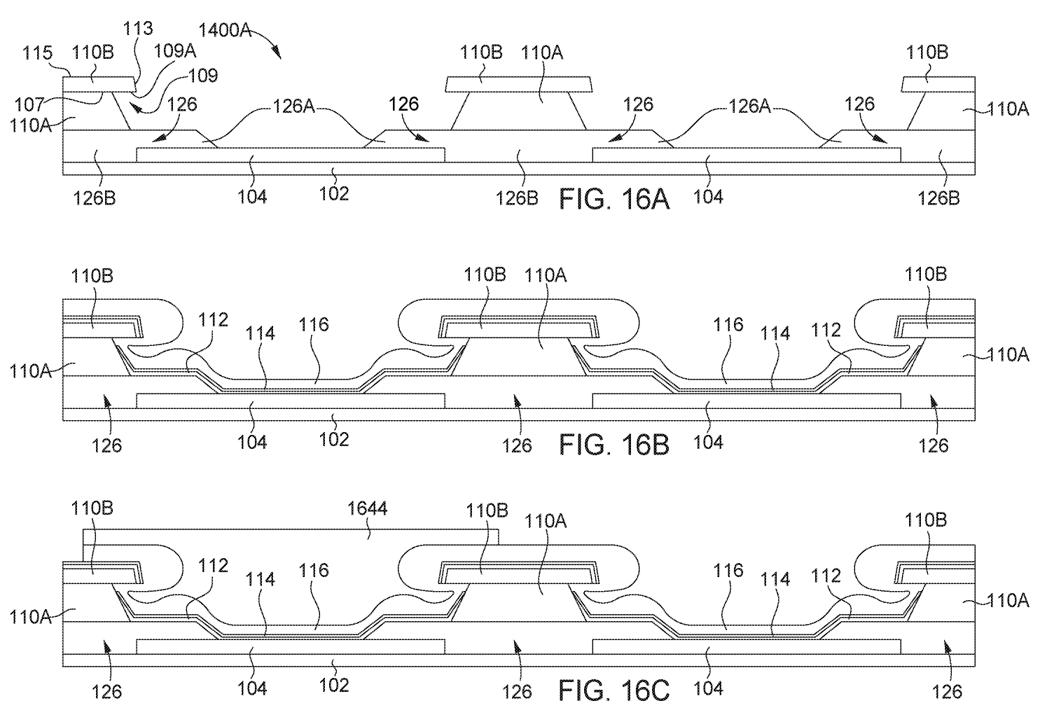

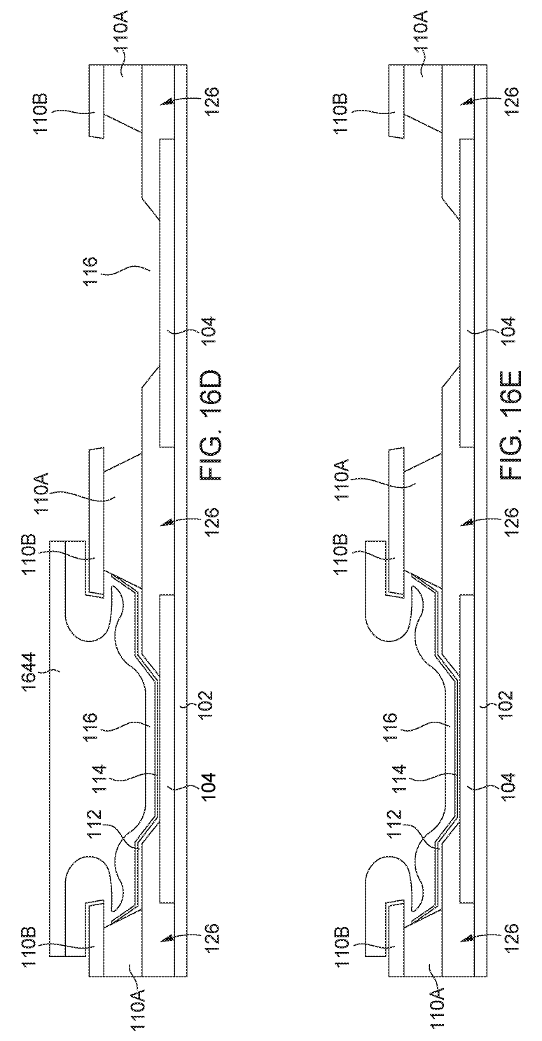

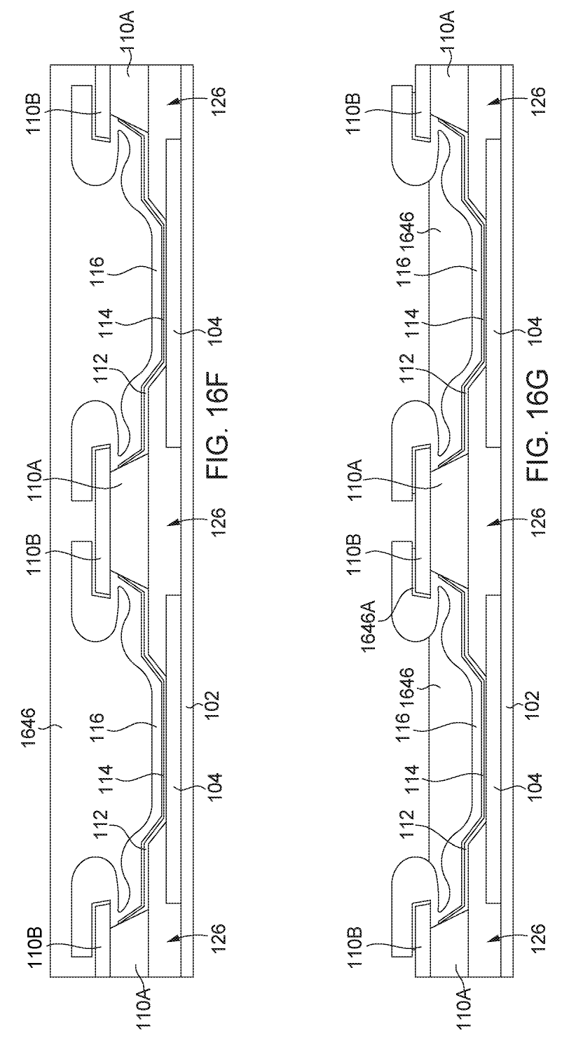

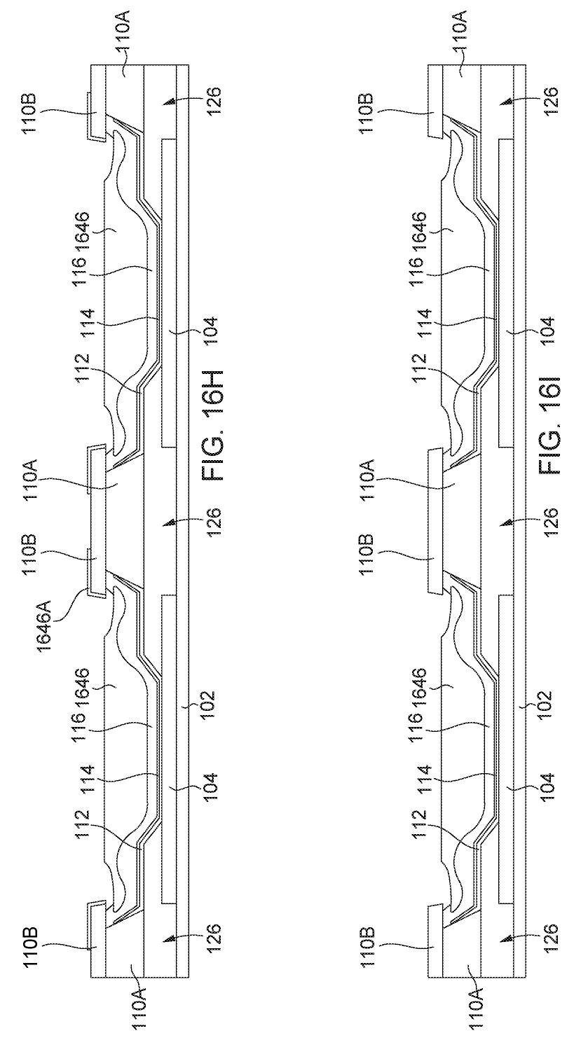

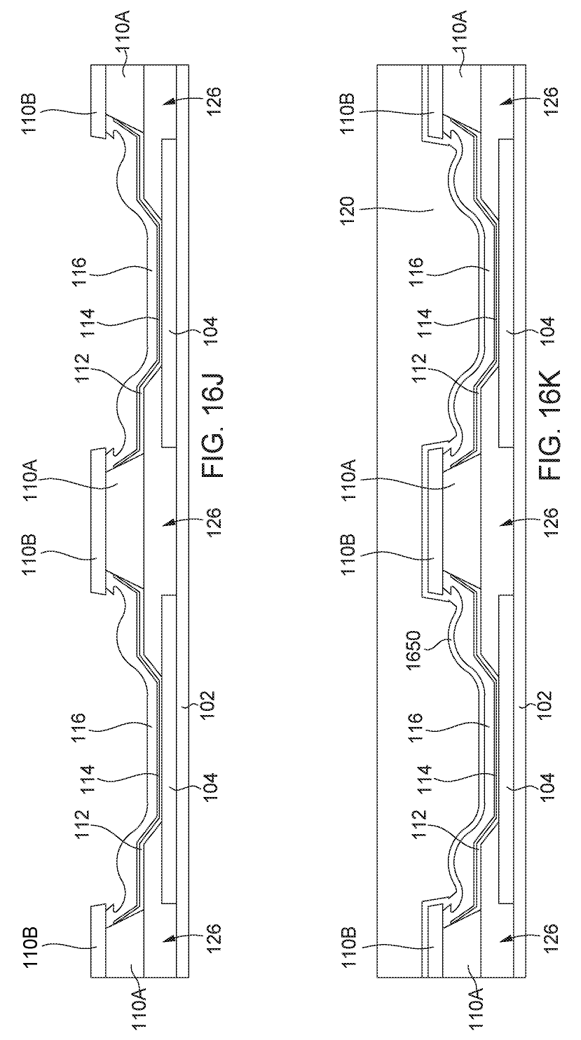

FIG. 15 is a flow diagram of a method 1500 for forming a sub-pixel circuit 1400. FIGS. 16A-16K are schematic, cross-sectional views of a substrate 102 during the method 1500 for forming the sub-pixel circuit 1400.

At operation 1501, as shown in FIG. 16A, a partial sub-pixel circuit 1400A is formed. A first structure 110A and a second structure 110B are deposited over a separation structure 126. The separation structure 126 includes a separation structure extension portion 126A and a separation structure body portion 126B. The separation structure extension portion 126A is disposed over an anode 104. The separation structure body portion 126B separates adjacent anodes 104. In one embodiment, the anode 104 is a metal-containing layer. The anode 104 is a layer stack of a first TCO layer, a second metal-containing layer disposed on the first TCO layer, and a third TCO layer disposed on the second metal-containing layer. The anode 104 is disposed on a substrate 102. The separation structure body portion 126B is disposed over substrate 102. In some examples, the separation structure body portion 126B is disposed on the substrate 102. The first structure 110A is disposed over the separation structure 126. The second structure 110B is disposed over the first structure 110A.

At operation 1502, as shown in FIG. 16B, the OLED materials 112, the cathode 114, and the encapsulation layer 116 of the first sub-pixel 108A are deposited. The shadowing of the overhang 109 provides for evaporation deposition each of the OLED material 112, and a cathode 114. The pixel structures 110 and the evaporation angle set by the evaporation source define the angle of deposition. For example, the pixel structures 110 provide for a shadowing effect during evaporation deposition with the evaporation angle set by the evaporation source configured to emit the deposition material at a particular angle with regard to the pixel structure 110.

The OLED material 112 is disposed over a sidewall 111 of the first structure 110A and the cathode 114 is disposed over the OLED material 112. In one example, the cathode extends past the OLED material 112 to contact the sidewall 111 of the first structure 110A of the pixel structures 110. The encapsulation layer 116 is deposited over the cathode 114. The encapsulation layer 116 is disposed over the cathode 114 that is disposed over the OLED material 112 on the sidewall 111 of the first structure 110A. In another example, the encapsulation layer 116 is disposed over the cathode 114. In another example, the encapsulation layer 116 extends past the cathode 114 to contact the sidewall 111 of the first structure 110A. In some examples, the encapsulation layer 116 extends to contact the second structure 110B at an underside surface of the overhang extension 109A. The encapsulation layer 116 extends over an upper surface 115 of the second structure 110B. In embodiments including capping layers, the capping layers are deposited between the cathode 114 and the encapsulation layer 116. The capping layers may be deposited by evaporation deposition.

In some examples, which may be combined with other embodiments, the OLED material 112 and the cathode 114 are disposed over a sidewall 113 of the second structure 110B of the pixel structures 110. In other embodiments, which may be combined with other embodiments, the OLED material 112 and the cathode 114 are disposed over the upper surface 115 of the second structure 110B of the pixel structures 110. In still other embodiments, which may be combined with other embodiments, the OLED material 112 and the cathode 114 end on the sidewall 111 of the first structure 110A, i.e., are not disposed over the sidewall 113 of the second structure 110B or the upper surface 115 of the second structure 110B.

In some embodiments, which may be combined with other embodiments, the encapsulation layer 116 extends to contact the second structure 110B at an underside surface of the overhang extension 109A and to be disposed over the OLED material 112 and the cathode 114 when the OLED material 112 and the cathode 114 are disposed over the sidewall 113 and upper surface 115 of the second structure 110B. In some embodiments, which may be combined with other embodiments, the encapsulation layer 116 ends at the sidewall 111 of the first structure 110A, i.e., is not disposed over the sidewall 113 of the second structure 110B, the upper surface 115 of the second structure 110B, or the underside surface of the overhang extension 109A of the pixel structures 110.

At operation 1503, as shown in FIG. 16C, a resist 1644 is disposed and patterned. The resist 1644 is disposed in the first sub-pixel 108A. The resist 1644 is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the resist 1644 determines whether the resist 1644 is a positive resist or a negative resist. The resist 1644 is patterned to protect the first sub-pixel 108A from the subsequent etching processes. The patterning is one of a photolithography, digital lithography process, or laser ablation process.

At operation 1504, as shown in FIG. 16D, portions of the OLED material 112, the cathode 114, and the encapsulation layer 116 exposed by the resist 1644 are removed. The portions of the OLED material 112, the cathode 114, and the encapsulation layer 116 may be removed using dry etching, wet etching, or a combination of dry etching and wet etching. For example, portions of the OLED material 112 may be removed using ashing (e.g., O₂ ashing). The surface of the anode 104 may be cleaned using UV ozone (O₃) cleaning. In some examples, the encapsulation layer 116 that is not exposed by the resist 1644 remains, while the OLED material 112 and the cathode 114 disposed on the upper surface 115 and sidewall 113 of the second structure 110B are removed. At operation 1505, as shown in FIG. 16E, the resist 1644 is removed.

Between operation 1505 and operation 1506, the operations 1501-1505 may be repeated to form the desired number of sub-pixels 106.

At operation 1506, as shown in FIG. 16F, a resist 1646 is disposed and patterned. The resist 1646 is disposed in the sub-pixels 106 and over the pixel structures 110. The resist 1646 is a positive resist or a negative resist. The chemical composition of the resist 1646 determines whether the resist 1646 is a positive resist or a negative resist. The resist 1646 is patterned to protect the sub-pixels 106 from the subsequent etching processes. The patterning is one of a photolithography, digital lithography process, or laser ablation process.

At operation 1507, as shown in FIG. 16G, a portion of the resist 1646 is removed to expose a portion of the encapsulation layer 116. The resist 1646 is removed using a photoresist ashing process. The photoresist ashing process may include using an oxygen (O₂) plasma, a fluorine (F₂) plasma, or a nitrogen/hydrogen plasma (N₂/H₂). The etch selectivity of the chemistry of the photoresist ashing process does not damage the encapsulation layer 116, thus enabling the encapsulation layer 116 to be exposed by the resist 1646.

At operation 1508, as shown in FIG. 16H, the portion of the encapsulation layer 116 that is exposed by the resist 1646 is removed. The exposed portions of the encapsulation layer 116 are removed using a dry etching process. The dry etching may include a fluorine-based plasma etching, such as a CF₄ of SF₆ plasma etching.

At optional operation 1509, as shown in FIG. 16I, a residual resist 1646A is removed from the second structures 110B. In some examples, the resist 1646 is deposited on an upper surface 115 of the second structure 110B in the locations previously occupied by the OLED material 112. During the removal of the encapsulation layer 116, this residual resist 1646A is protected by the encapsulation layer 116 and is not removed. The residual resist 1646A is removed using a photoresist ashing process.

At operation 1510, as shown in FIG. 16J, the resist 1646 is removed from the sub-pixels 106. At optional operation 1511, as shown in FIG. 16K, a panel cover layer 1650 is disposed over the sub-pixel circuit 1400. The panel cover layer 1650 is disposed on an upper surface 115 of the second structure 110B. The panel cover layer 1650 includes TCO, metallic materials, or dielectric materials. For example, the panel cover layer 1650 may include an indium-tin-oxide (ITO), an indium zinc oxide (IZO), silicon nitride, silicon oxide, or combinations thereof. The panel cover layer 1650 may be disposed globally over the sub-pixel circuit 1400 to reduce the likelihood of moisture invasion at the interface of the encapsulation layer 116 and the first structure 110A.

At operation 1512, as shown in FIG. 16K, a global passivation layer 120 is disposed over the sub-pixel circuit 1400. In embodiments with the panel cover layer 1650, the global passivation layer 120 is disposed on the panel cover layer 1650.

In summation, a sub-pixel circuit includes a substrate, anodes patterned on the substrate and defined by adjacent separation structures disposed on the substrate. The sub-pixel circuit has a plurality of sub-pixels. Each sub-pixel includes adjacent pixel structures, with adjacent sub-pixels sharing the adjacent pixel structures. Each adjacent pixel structures includes a first structure disposed over the substrate. During manufacture of the sub-pixel circuit, the adjacent pixel structures include adjacent overhangs of a second structure. The adjacent overhangs are defined by an overhang extension of the second structure extending laterally past an upper surface of a first structure. The second structure is disposed over the first structure. After deposition of an OLED material, a cathode, and a encapsulation layer, the second structure is removed from the sub-pixel circuit. By removing the second structure, the viewing angle of the sub-pixel circuit at ultra-high pixel per inch (PPI) is increased, as the second structure may block the emission path of the light emitted by the sub-pixel. In addition, removal of the second structure decreases the amount of ambient reflection within the sub-pixel circuit. The second structures may increase the amount of ambient light that is reflected off of the display. By removing the second structures, and thus reducing the ambient reflection, the image contrast of the display may be increased.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a substrate; and
a plurality of sub-pixels defined by adjacent pixel structures, each sub-pixel comprising:
the adjacent pixel structures disposed over the substrate, wherein each pixel structure comprises a first structure disposed over the substrate;
an anode;
an organic light emitting diode (OLED) material disposed over the anode;
a cathode disposed over the OLED material; and
an encapsulation layer disposed over the cathode, the encapsulation layer having an encapsulation overhang, the encapsulation overhang extends from a sidewall of the first structure and has an upper surface coplanar with a top surface of the first structure, the encapsulation layer having a gap between the encapsulation overhang and a portion of the encapsulation layer disposed over the cathode; and
a global layer disposed over the plurality of sub-pixels, wherein the global layer is disposed on the top surface of the first structure and the upper surface of the encapsulation overhang.

2. The device of claim 1, further comprising an intermediate structure disposed over an upper surface of the first structure.

3. The device of claim 2, wherein the intermediate structure comprises a silicon nitride (Si₃N₄), a silicon oxide (SiO₂), a silicon oxynitride (SiOₓN_{y}), a transparent conductive oxide (TCO) material, or a metal material.

4. The device of claim 1, wherein the first structure comprises a metal material or an inorganic material.

5. The device of claim 4, wherein the metal material comprises a copper (Cu), aluminum (Al), aluminum neodymium (AlNd), molybdenum (Mo), molybdenum tungsten (MoW), a transparent conductive oxide (TCO) material, or combinations thereof.

6. The device of claim 4, wherein the inorganic material comprises amorphous silicon (a-Si), silicon nitride (Si₃N₄), silicon oxide (SiO₂), silicon oxynitride (Si₂N₂O), germanium (Ge), germanium arsenide (GeAs III or IV), or combinations thereof.

7. The device of claim 1, further comprising a panel cover layer disposed over the plurality of sub-pixels.

8. The device of claim 7, wherein the panel cover layer comprises a silicon nitride (Si₃N₄), a silicon oxide (SiO₂), a silicon oxynitride (SiOₓN_{y}), a transparent conductive oxide (TCO) material, or a metal material.

9. A device, comprising:
a substrate; and
a plurality of sub-pixels defined by adjacent pixel structures, each sub-pixel comprising:
the adjacent pixel structures disposed over the substrate, wherein each pixel structure comprises a first structure disposed over the substrate;
an anode;
an organic light emitting diode (OLED) material disposed over the anode;
a cathode disposed over the OLED material; and
an encapsulation layer disposed over the cathode, the encapsulation layer having an encapsulation overhang, the encapsulation overhang extends from a sidewall of the first structure and has an upper surface coplanar with a top surface of the first structure, the encapsulation layer having a gap between the encapsulation overhang and a portion of the encapsulation layer disposed over the cathode;
a panel cover layer disposed over the plurality of sub-pixels, wherein the panel cover layer is disposed on the upper surface of the first structure and the upper surface of the encapsulation overhang; and
a global passivation layer disposed over the panel cover layer.

10. The device of claim 9, further comprising an intermediate structure disposed over an upper surface of the first structure.

11. The device of claim 10, wherein the intermediate structure comprises a silicon nitride (Si₃N₄), a silicon oxide (SiO₂), a silicon oxynitride (SiOₓN_{y}), a transparent conductive oxide (TCO) material, or a metal material.

12. The device of claim 11, wherein the first structure comprises a metal material comprising a copper (Cu), aluminum (Al), aluminum neodymium (AlNd), molybdenum (Mo), molybdenum tungsten (MoW), a transparent conductive oxide (TCO) material, or combinations thereof.

13. The device of claim 12, wherein the first structure comprises an inorganic material comprising amorphous silicon (a-Si), silicon nitride (Si₃N₄), silicon oxide (SiO₂), silicon oxynitride (Si₂N₂O), germanium (Ge), germanium arsenide (GeAs III or IV), or combinations thereof.

14. The device of claim 9, wherein the panel cover layer comprises a silicon nitride (Si₃N₄), a silicon oxide (SiO₂), a silicon oxynitride (SiOₓN_{y}), a transparent conductive oxide (TCO) material, or a metal material.

15. A method of forming a device, comprising:
disposing a first resist in a plurality of sub-pixels of a sub-pixel circuit, wherein the sub-pixel circuit are defined by adjacent pixel structures, each sub-pixel comprising:
the adjacent pixel structures comprising:
a first structure disposed over a substrate; and
a second structure disposed over a first structure, wherein the second structure comprises an overhang extension extending laterally past an upper surface of a first structure to form an overhang;
an anode;
an organic light emitting diode (OLED) material disposed over the anode, wherein the OLED material is disposed under the overhang and extends to contact a sidewall of the first structure;
a cathode disposed over the OLED material, wherein the cathode is disposed under the overhang; and
an encapsulation layer disposed over the cathode, wherein the encapsulation layer is disposed under the overhang and extends past an endpoint of the cathode to contact the sidewall of the first structure;
removing a portion of the first resist to expose a portion of the encapsulation layer;
removing the portion of the encapsulation layer that is exposed by the first resist to expose the second structure;
removing the first resist;
disposing a second resist in the plurality of sub-pixels;
removing a portion of the second resist to expose the second structure;
removing the second structure exposed by the second resist; and
removing the second resist.

16. The method of claim 15, wherein the second structure is removed using a wet etch process or a dry etch process.

17. The method of claim 16, wherein the wet etch process is an oxalic wet etch.

18. The method of claim 15, further comprising:
disposing a panel cover layer over the sub-pixel circuit.

19. The method of claim 18, wherein the panel cover layer comprises a silicon nitride (Si₃N₄), a silicon oxide (SiO₂), a silicon oxynitride (SiOₓN_{y}) , a transparent conductive oxide (TCO) material, or a metal material.

20. The method of claim 15, wherein the overhang of the pixel structure is configured to define deposition angles of the OLED material, the cathode, and the encapsulation layer.
